(19) United States
(12) Patent Application Publication
(10) Pub. No.: US 2026/0123213 A1
(43) Pub. Date: Apr. 30, 2026

(54) ELECTRONIC DEVICE

(71) Applicant: Samsung Display Co., LTD., Yongin-si (KR)

(72) Inventors: SEUNGJAE KANG, Yongin-si (KR); KIYONG KIM, Yongin-si (KR); HEEJU WOO, Yongin-si (KR); CHOLONG WON, Yongin-si (KR); DAEHWAN JANG, Yongin-si (KR); HYUNGBIN CHO, Yongin-si (KR); Kyungbin CHOI, Yongin-si (KR)

(21) Appl. No.: 19/315,106

(22) Filed: Aug. 29, 2025

(30) Foreign Application Priority Data
Oct. 25, 2024 (KR) 10-2024-0147148

(51) Int. Cl. H10K 59/131; H10K 59/124

(52) U.S. Cl. CPC H10K 59/131; H10K 59/124

(57) ABSTRACT

An electronic device includes a display panel including a display area and a non-display area next (adjacent) to the display area and an electronic component disposed in the non-display area and electrically connected to the display panel. The display panel includes a base layer, a pixel disposed on the base layer, a signal line electrically connected to the pixel, and a signal pad electrically connected to the signal line. The signal pad includes a first conductive pattern connected to an end part of the signal line, a second conductive pattern disposed on the first conductive pattern and connected to the first conductive pattern, and an insulating pattern disposed between the end part and the second conductive pattern. An opening is defined through the second conductive pattern and the insulating pattern to overlap the end part. The electronic component includes a bump contacting the second conductive pattern.

This application claims priority to Korean Patent Application No. 10-2024-0147148, filed on Oct. 25, 2024, and all the benefits accruing therefrom under 35 U.S.C. § 119, the content of which in its entirety is herein incorporated by reference.

### BACKGROUND

### 1. Field

The disclosure relates to an electronic device. More particularly, the disclosure relates to an electronic device including a pad area.

### 2. Description of Related Art

Multimedia electronic devices, such as televisions, mobile phones, tablet computers, navigation devices, and game devices, include a display device displaying an image and sensing an external input.

The display device includes a display area activated in response to electrical signals. The display device senses external inputs applied thereto through the display area and displays images to provide a user with information.

The electronic device includes a display device and a circuit board. The display device is connected to a main board via the circuit board. A driving chip is mounted on the display device. The driving chip is electrically connected to the display device via pads arranged in a non-display area of the display device.

### SUMMARY

The disclosure provides an electronic device including signal pads with improved bonding reliability.

An embodiment of the inventive concept provides an electronic device including a display panel including a display area and a non-display area next (adjacent) to the display area and an electronic component disposed in the non-display area and electrically connected to the display panel. The display panel includes a base layer, a pixel disposed on the base layer, a signal line electrically connected to the pixel, and a signal pad electrically connected to the signal line. The signal pad includes a first conductive pattern connected to an end part of the signal line, a second conductive pattern disposed on the first conductive pattern and connected to the first conductive pattern, and an insulating pattern disposed between the end part of the signal line and the second conductive pattern. An opening is defined through the second conductive pattern and the insulating pattern to overlap the end part of the signal line, and the electronic component includes a bump that contacts the second conductive pattern.

In an embodiment, a width of the opening measured at an upper surface of the insulating pattern is smaller than a width of the opening measured at a lower surface of the insulating pattern.

In an embodiment, the opening includes a first area and a second area under the first area, and a width of the first area is smaller than a width of the second area.

In an embodiment, the opening has a bottle shape when viewed in a cross-section.

In an embodiment, the insulating pattern includes a material with a lower hardness than a hardness of the second conductive pattern.

In an embodiment, a center of the opening of the insulating pattern corresponds to a center of the bump.

In an embodiment, the insulating pattern includes a first portion next (adjacent) to the bump and a second portion under the first portion, and the first portion protrudes toward a center of the bump further than the second portion.

In an embodiment, the display panel further includes an adhesive layer that contacts the signal pad and the bump.

In an embodiment, the adhesive layer is filled into an inner side surface of the opening.

In an embodiment, an opening is defined through the first conductive pattern to correspond to the opening defined through the insulating pattern.

In an embodiment, the display panel further includes a plurality of insulating layers disposed on the base layer and covering the end part of the signal line, and an opening is defined through the plurality of insulating layers to correspond to the opening defined through the insulating pattern.

In an embodiment, a portion of the insulating pattern is disposed in the opening defined through the plurality of insulating layers, and the portion of the insulating pattern contacts an inner side surface of the plurality of insulating layers through which the opening is defined.

In an embodiment, the signal pad further includes a third conductive pattern including a first portion disposed on the second conductive pattern and a second portion disposed in the opening defined through the insulating pattern.

In an embodiment, the end part of the signal line extends in a first direction in a plan view, the insulating pattern is provided in plural in a manner that insulating patterns are arranged in the first direction.

In an embodiment, the display panel further includes a plurality of insulating layers disposed on the end part of the signal line, and the end part of the signal line is connected to the first conductive pattern via a contact hole penetrating through the plurality of insulating layers.

An embodiment of the inventive concept provides an electronic device including a display panel including a display area and a non-display area next (adjacent) to the display area and an electronic component disposed in the non-display area and electrically connected to the display panel. The display panel includes a base layer, a pixel disposed on the base layer, a signal line electrically connected to the pixel, and a signal pad electrically connected to the signal line. The signal pad includes a first conductive pattern connected to an end part of the signal line, a second conductive pattern disposed on the first conductive pattern and connected to the first conductive pattern, and an insulating pattern disposed between the end part of the signal line and the second conductive pattern. The electronic component includes a bump that contacts the second conductive pattern, the insulating pattern includes a first portion and a second portion disposed on the first portion, and at least a portion of the second portion protrudes from the first portion toward a center of the bump.

In an embodiment, the second portion has a width greater than a width of the first portion when viewed in a cross-section.

In an embodiment, the first portion of the insulating pattern extends to contact one side surface of the first conductive pattern when viewed in the cross-section.

In an embodiment, the display panel further includes a plurality of insulating layers disposed on the base layer and covering the end part of the signal line, and the first portion of the insulating pattern extends to contact the plurality of insulating layers when viewed in the cross-section.

In an embodiment, in a plan view, the end part of the signal line extends in a first direction, the insulating pattern is provided in plural in a manner that insulating patterns include first insulating patterns and second insulating patterns, which are arranged in a zigzag pattern in a second direction intersecting the first direction, and the insulating patterns are arranged in the first direction.

In an embodiment, when viewed in the plane, the end part of the signal line extends in the first direction, the insulating pattern includes a first insulating pattern and a second insulating pattern facing the first insulating pattern in a second direction intersecting the first direction, the insulating pattern is provided in plural in a manner that insulating patterns are arranged in the first direction.

According to the above, since the signal pads of the electronic device include the insulating pattern through which the opening is defined to overlap the end part of the signal line, anchoring is formed as the insulating pattern is inclined in the bonding process.

According to the above, the bonding reliability between the signal pad and the electronic components is improved due to the anchoring of the insulating pattern under the relatively high temperature and relatively high humidity conditions, and the bonding resistance is reduced.

### BRIEF DESCRIPTION OF THE DRAWINGS

The above and other embodiments, advantages and features of this disclosure will become more apparent by describing in further detail embodiments thereof with reference to the accompanying drawings, in which:

FIG. 1 is a perspective view of an embodiment of an electronic device according to the disclosure;

FIG. 2 is an exploded perspective view of an embodiment of an electronic device according to the disclosure;

FIG. 3 is a cross-sectional view of an embodiment of a display device according to the disclosure;

FIG. 4 is a plan view of an embodiment of a display panel according to the disclosure;

FIG. 5 is a cross-sectional view of an embodiment of a display panel according to the disclosure;

FIG. 6 is an exploded perspective view of an embodiment of a pad area of a display device according to the disclosure;

FIG. 7 is a plan view of an embodiment of a pad area of a display panel according to the disclosure;

FIG. 8A is an enlarged plan view of an embodiment of a pad according to the disclosure, and FIGS. 8B and 8C are cross-sectional views respectively taken along lines I-I′ and II-II′ of FIG. 8A;

FIG. 9A is an enlarged plan view of an embodiment of a pad according to the disclosure, and FIG. 9B is a cross-sectional view taken along line III-III′ of FIG. 9A;

FIG. 10A is a cross-sectional view taken along line III-III′ of FIG. 9A before an embodiment of a pad and a bump are bonded according to the disclosure, FIG. 10B is a cross-sectional view taken along line III-III′ of FIG. 9A after an embodiment of the pad and the bump are bonded according to the disclosure, and FIG. 10C is an enlarged cross-sectional view of an area of FIG. 10B;

FIG. 11 is a cross-sectional view of an embodiment of a pad according to the disclosure;

FIG. 12A is a plan view of an embodiment of a pad according to the disclosure, and FIG. 12B is a cross-sectional view taken along line IV-IV′ of FIG. 12A;

FIGS. 13A and 13B are plan views of an embodiment of pads according to the disclosure;

FIG. 14A is a plan view of an embodiment of a pad according to the disclosure, and FIG. 14B is a cross-sectional view taken along line V-V′ of FIG. 14A;

FIGS. 14C and 14D are plan views of an embodiment of pads according to the disclosure; and

FIGS. 15A to 15G are cross-sectional views of an embodiment of a method of manufacturing an electronic device according to the disclosure.

### DETAILED DESCRIPTION

In the disclosure, it will be understood that when an element (or area, layer, or portion) is referred to as being “on”, “connected to” or “coupled to” another element or layer, it may be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the drawing figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the disclosure will be described with reference to accompanying drawings.

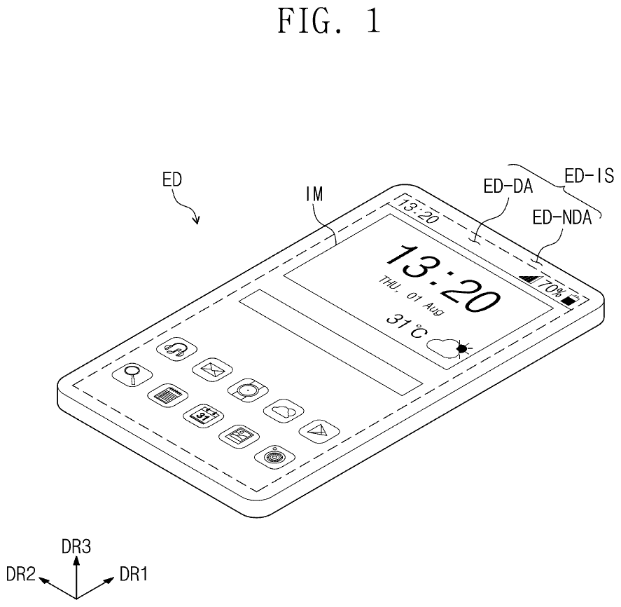

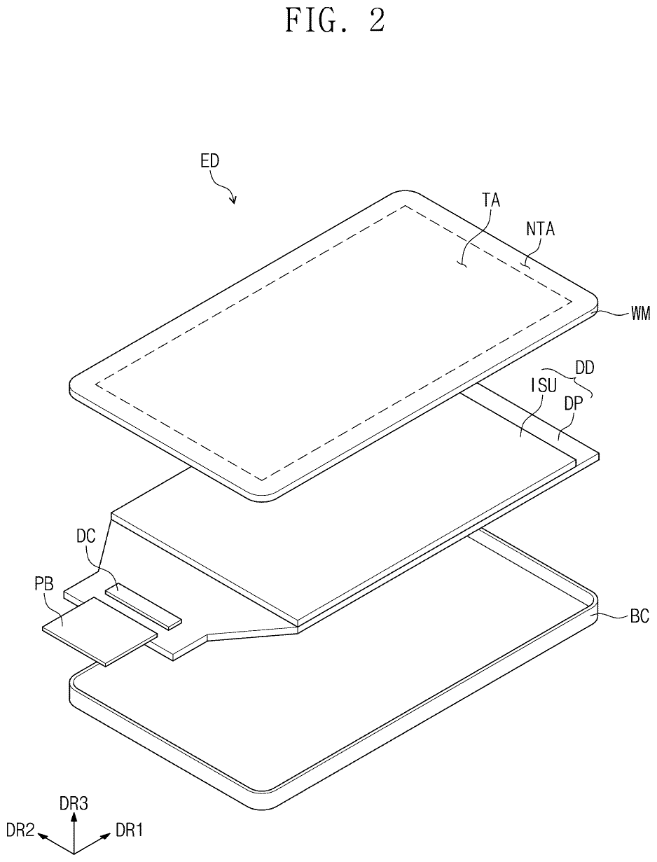

FIG. 1 is a perspective view of an embodiment of an electronic device ED according to the disclosure. FIG. 2 is an exploded perspective view of an embodiment of the electronic device ED according to the disclosure.

FIGS. 1 and 2 show a mobile phone as an illustrative embodiment of the electronic device ED. The electronic device ED may be applied to a large-sized electronic device, such as a television set, a monitor, etc., and a small and medium-sized electronic device, such as a tablet computer, a car navigation unit, a game unit, a smart watch, etc.

Referring to FIG. 1, the electronic device ED may display an image IM through a display surface ED-IS. FIG. 1 illustrates icon images as an illustrative embodiment of the image IM. The display surface ED-IS may be substantially parallel to a plane defined by a first direction DR1 and a second direction DR2. A third direction DR3 may indicate a normal line direction of the display surface ED-IS, i.e., a thickness direction of the electronic device ED. In the following descriptions, an expression “in a plan view” or “in a plane” may mean a state of being viewed in the third direction DR3. Front (or upper) and rear (or lower) surfaces of layers or units described below may be distinguished from each other with respect to the third direction DR3.

The display surface ED-IS may include a display area ED-DA through which the image IM is displayed and a non-display area ED-NDA next (adjacent) to the display area ED-DA. The non-display area ED-NDA may be an area in which the image IM is not displayed. However, the disclosure should not be limited thereto or thereby, and the non-display area ED-NDA may be defined next (adjacent) to one side of the display area ED-DA or may be omitted.

Referring to FIG. 2, the electronic device ED may include a window WM, a display device DD, and a housing BC. The housing BC may accommodate the display device DD and may be coupled to the window WM. Although not shown in drawing figures, the electronic device ED may further include other electronic modules accommodated in the housing BC and electrically connected to a display device DD. In an embodiment, the electronic device ED may further include a main board, a circuit module disposed (e.g., mounted) on the main board, a camera module, a power module, or the like, for example.

The window WM may be disposed above the display device DD and may transmit the image provided from the display device DD to the outside. The window WM may include a transmission area TA and a non-transmission area NTA. The transmission area TA may overlap the display area ED-DA of FIG. 1 and may have a shape corresponding to that of the display area ED-DA.

The non-transmission area NTA may overlap the non-display area ED-NDA (refer to FIG. 1) and may have a shape corresponding to that of the non-display area ED-NDA (refer to FIG. 1). The non-transmission area NTA may have a relatively low light transmittance compared with that of the transmission area TA.

The display device DD may generate the image and may sense an external input. The display device DD may include the display panel DP and an input sensor ISU. Although not shown in drawing figures, the display device DD may further include an anti-reflective member disposed on the input sensor ISU. The anti-reflective member may include a polarizer and a retarder or may include a color filter and a black matrix.

The display panel DP may be a light-emitting type display panel, however, it should not be particularly limited. In an embodiment, the display panel DP may be an organic light-emitting display panel or an inorganic light-emitting display panel, for example. A light-emitting layer of the organic light-emitting display panel may include an organic light-emitting material. A light-emitting layer of the inorganic light-emitting display panel may include a quantum dot, a quantum rod, or a nano-LED. Hereinafter, the organic light-emitting display panel will be described as an illustrative embodiment of the display panel DP.

The input sensor ISU may include one of a capacitive sensor, an optical sensor, an ultrasonic sensor, and an electromagnetic induction sensor. The input sensor ISU may be formed on the display panel DP through successive processes or may be attached to an upper portion of the display panel DP using an adhesive layer after being separately manufactured.

The display device DD may further include a driving chip DC and a circuit board PB. FIG. 2 shows a structure in which the driving chip DC is disposed (e.g., mounted) on the display panel DP, however, it should not be limited thereto or thereby. In an embodiment, the driving chip DC may be disposed (e.g., mounted) on the circuit board PB. In the illustrated embodiment, the driving chip DC and the circuit board PB, which are electrically connected to the display panel DP, may be also referred to as electronic components.

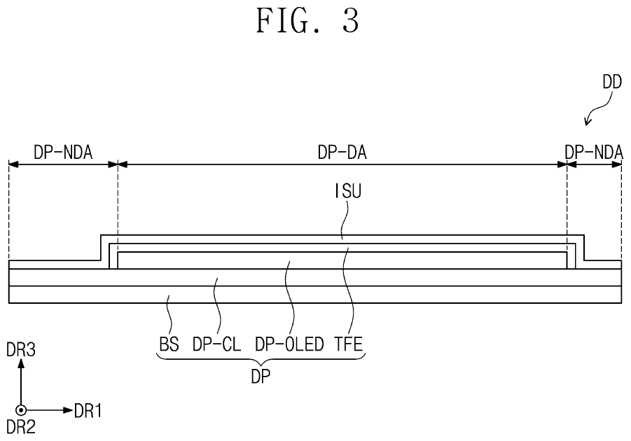

The driving chip DC may generate a driving signal desired for an operation of the display panel DP in response to a control signal provided from the circuit board PB. The circuit board PB bonded to the display panel DP may be bent and may be disposed on a rear surface of the display panel DP. The circuit board PB may be disposed at one end of a base layer BS (refer to FIG. 3) and may be electrically connected to a circuit element layer DP-CL (refer to FIG. 3).

In the display device DD, the display panel DP may be partially bent such that the driving chip DC may face downward. A portion of the non-display area ED-NDA (refer to FIG. 1) of the display panel DP may be bent. However, the bent portion should not be limited thereto or thereby, and the circuit board PB may be bent.

In the above descriptions, the mobile phone terminal is shown as the electronic device ED, however, in the disclosure, it is sufficient for the electronic device ED to include two or more bonded electronic components. The display panel DP and the driving chip DC disposed (e.g., mounted) on the display panel DP may be different electronic components, and these alone may constitute the electronic device ED. In an alternative embodiment, only the display panel DP and the circuit board PB connected to the display panel DP may constitute the electronic device ED, and only the main board and the electronic modules disposed (e.g., mounted) on the main board may constitute the electronic device ED. Hereinafter, the display device DD and the electronic device ED will be described with a focus on the bonding structure between the display panel DP and the driving chip DC disposed (e.g., mounted) on the display panel DP.

FIG. 3 is a cross-sectional view of an embodiment of the display device DD according to the disclosure.

Referring to FIG. 3, the display panel DP may include the base layer BS, the circuit element layer DP-CL, a display element layer DP-OLED, and a thin film encapsulation layer TFE, which are stacked on the base layer BS. The input sensor ISU may be disposed on the thin film encapsulation layer TFE.

The display panel DP may include a display area DP-DA and a non-display area DP-NDA. The display area DP-DA of the display panel DP may correspond to the display area ED-DA shown in FIG. 1 or the transmission area TA shown in FIG. 2, and the non-display area DP-NDA may correspond to the non-display area ED-NDA shown in FIG. 1 or the non-transmission area NTA shown in FIG. 2.

The base layer BS may include the display area DP-DA and the non-display area DP-NDA around the display area DP-DA. The base layer BS may include a synthetic resin film. The base layer BS may have a multi-layer structure. In an embodiment, the base layer BS may have a three-layer structure of a synthetic resin layer, an inorganic layer, and a synthetic resin layer, for example. In particular, the synthetic resin layer may include a polyimide-based resin, however, it should not be limited thereto or thereby. The synthetic resin layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin. The base layer BS may include a glass substrate, a metal substrate, or an organic/inorganic composite material substrate.

The circuit element layer DP-CL may include at least one insulating layer and a circuit element. The insulating layer may include at least one inorganic layer and at least one organic layer. The circuit element may include signal lines and a pixel driving circuit.

The insulating layer, a semiconductor layer, and a conductive layer may be formed by coating and deposition processes. Then, the insulating layer, the semiconductor layer, and the conductive layer may be selectively patterned by a photolithography process and an etching process. A semiconductor pattern, a conductive pattern, and the signal line may be formed by the above-mentioned processes. Patterns disposed at the same layer may be formed through the same process. The expression “the patterns are formed through the same process”, as used herein, means that the patterns include the same material and have the same stack structure.

The display element layer DP-OLED may include an organic light-emitting element. The display element layer DP-OLED may further include an organic layer such as a pixel definition layer.

The thin film encapsulation layer TFE may be disposed on the circuit element layer DP-CL to cover the display element layer DP-OLED. The thin film encapsulation layer TFE may overlap the display area DP-DA and the non-display area DP-NDA. The thin film encapsulation layer TFE may overlap at least a portion of the non-display area DP-NDA. The thin film encapsulation layer TFE may protect the pixels from moisture, oxygen, and a foreign substance, however, it should not be limited thereto or thereby. In an embodiment, the thin film encapsulation layer TFE may further include an additional insulating layer. In an embodiment, the thin film encapsulation layer TFE may further include an optical insulating layer to control a refractive index.

In an embodiment, a sealing substrate may be provided in place of the thin film encapsulation layer TFE. In this case, the sealing substrate may face the base layer BS, and the circuit element layer DP-CL and the display element layer DP-OLED may be disposed between the sealing substrate and the base layer BS.

The input sensor ISU may be disposed directly on the display panel DP. In the disclosure, the expression “a component A is disposed directly on a component B” means that no intervening elements are between the component A and the component B. In the illustrated embodiment, the input sensor ISU may be formed through successive processes with the display panel DP, however, the disclosure should not be limited thereto or thereby. In an embodiment, the input sensor ISU may be provided as an individual panel and then may be coupled to the display panel DP by an adhesive layer. In an embodiment, the input sensor ISU may be omitted.

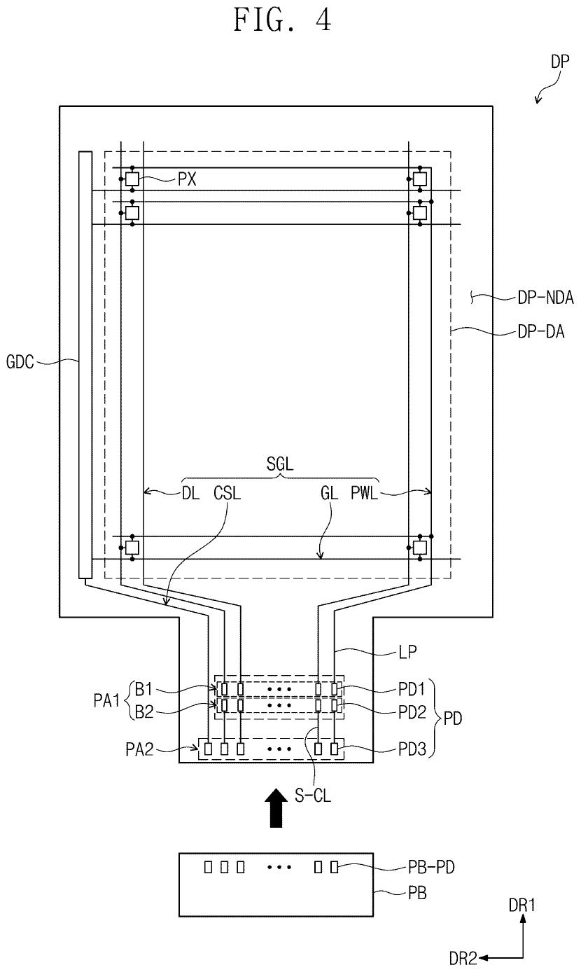

FIG. 4 is a plan view of an embodiment of the display panel DP according to the disclosure. FIG. 4 shows a shape of the display panel DP in a plan view.

Referring to FIG. 4, the display panel DP may include a plurality of pixels PX, a gate driving circuit GDC, a plurality of signal lines SGL, and a plurality of signal pads PD.

The pixels PX may be arranged in the display area DP-DA. Each of the pixels PX may include a light-emitting element and a pixel driving circuit connected to the light-emitting element. The gate driving circuit GDC may sequentially output gate signals to a plurality of gate lines GL described later. The gate driving circuit GDC may include a transistor formed through the same process as a transistor of the pixel PX, e.g., a low temperature polycrystalline silicon (“LTPS”) process or a low temperature polycrystalline oxide (“LTPO”) process. The display panel DP may further include another driving circuit that applies a light emission control signal to the pixels PX.

The signal lines SGL may include the gate lines GL, data lines DL, a power line PWL, and a control signal line CSL. Each of the gate lines GL may be connected to a corresponding pixel PX among the pixels PX, and each of the data lines DL may be connected to a corresponding pixel PX among the pixels PX. The power line PWL may be connected to the pixels PX. In an embodiment, the data lines DL and the power line PWL may include lines LP, respectively, disposed in the non-display area DP-NDA and electrically and directly connected to the first pads PD1. The control signal line CSL may be connected to the gate driving circuit GDC and may provide control signals to the gate driving circuit GDC.

The signal lines SGL may overlap the display area DP-DA and the non-display area DP-NDA. Each of the signal lines SGL may include a line part. The line part may overlap the display area DP-DA and the non-display area DP-NDA.

The signal pads PD may include first pads PD1, second pads PD2, and third pads PD3. In the disclosure, the signal pads PD may be also referred to as pads. An area in which the first pads PD1 and the second pads PD2 are arranged may be also referred to as a first pad area PA1, and an area in which the third pads PD3 are arranged may be also referred to as a second pad area PA2.

The first pad area PA1 may be an area bonded to the driving chip DC (refer to FIG. 2), and the second pad area PA2 may be an area bonded to the circuit board PB. The first pad area PA1 may include a first area B1 in which the first pads PD1 are arranged and a second area B2 in which the second pads PD2 are arranged. The first pad area PA1 and the second pad area PA2 may be disposed in the non-display area DP-NDA. The first pad area PA1 and the second pad area PA2 may be spaced apart from each other in the first direction DR1. The first pad area PA1 may be closer to the display area DP-DA than the second pad area PA2 is, the second pad area PA2 may be spaced apart from the display area DP-DA, and the first pad area PA1 may be disposed between the second pad area PA2 and the display area DP-DA. One pad row is arranged in the first pad area PA1 as an illustrative embodiment, however, the disclosure should not be limited thereto or thereby, and a plurality of pad rows may be arranged in the first pad area PA1.

Each of the first pads PD1 may be connected to a corresponding data line DL among the data lines DL. Although not shown in drawing figures, the first pads PD1 and the second pads PD2 may be electrically connected to each other. The second pads PD2 may be connected to the third pads PD3 via connection signal lines S-CL.

The circuit board PB may include a plurality of circuit pads PB-PD. The circuit pads PB-PD may be arranged in the second direction DR2. The circuit pads PB-PD of the circuit board PB may be connected to the third pads PD3 of the second pad area PA2.

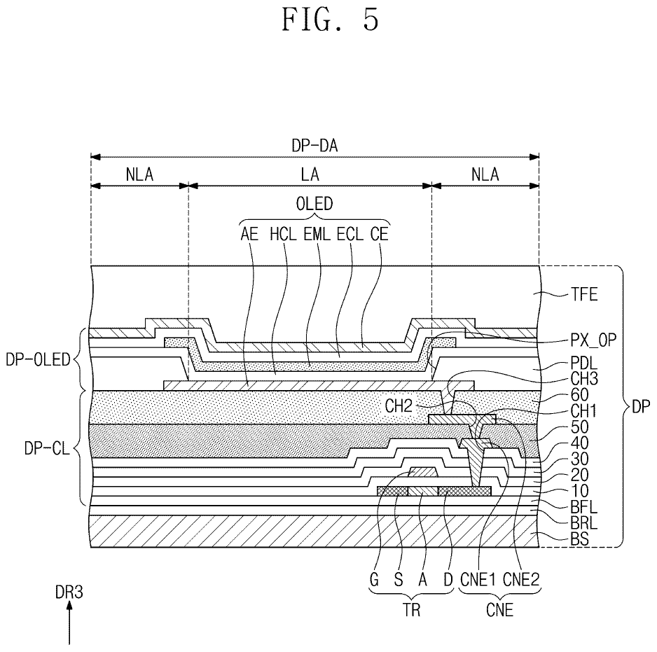

FIG. 5 is a cross-sectional view of an embodiment of the display panel DP according to the disclosure.

Referring to FIG. 5, the display area DP-DA may include a light-emitting area LA corresponding to each pixel PX (refer to FIG. 4) and a non-light-emitting area NLA around the light-emitting area LA. The pixel PX (refer to FIG. 4) may include the light-emitting element OLED and the driving circuit connected to the light-emitting element OLED. In detail, each pixel PX (refer to FIG. 4) may include the transistor TR and the light-emitting element OLED.

Referring to FIG. 5, the display panel DP may include the base layer BS, the circuit element layer DP-CL disposed on the base layer BS, the display element layer DP-OLED, and the thin film encapsulation layer TFE.

A plurality of insulating layers may be disposed on the base layer BS. The insulating layers may include a barrier layer BRL and a buffer layer BFL. The insulating layers may further include first, second, third, fourth, fifth, and sixth insulating layers 10, 20, 30, 40, 50, and 60. The barrier layer BRL may prevent a foreign substance from entering from the outside. The barrier layer BRL may include a silicon oxide layer and a silicon nitride layer. Each of the silicon oxide layer and the silicon nitride layer may be provided in plural, and the silicon oxide layers may be alternately stacked with the silicon nitride layers.

The buffer layer BFL may improve an adhesive force between the semiconductor pattern and the base layer BL or between the conductive pattern and the base layer BL. The buffer layer BFL may include a silicon oxide layer and a silicon nitride layer. The silicon oxide layer may be alternately stacked with the silicon nitride layer.

The semiconductor pattern may be disposed on the buffer layer BFL. The semiconductor pattern may include polycrystalline silicon, an amorphous silicon, crystalline silicon, or metal oxide. FIG. 5 shows a portion of the semiconductor pattern, and the semiconductor pattern may be further disposed in other areas of the display panel DP when viewed in a cross-section. The semiconductor pattern may be doped with an N-type dopant or a P-type dopant. The semiconductor pattern may include a high-doped region and a low-doped region. The high-doped region may have a conductivity greater than that of the low-doped region and may substantially serve as a source electrode and a drain electrode of the transistor TR. The low-doped region may substantially correspond to an active (or channel) of the transistor TR.

A drain D, an active A, and a source S may be disposed on the buffer layer BFL. The drain D, the active A, and the source S may form the transistor TR with a gate G described later. When the display panel DP includes another transistor in addition to the transistor TR, the transistor may include a material different from that of the transistor TR and may be disposed at a different layer from the transistor TR. The source S, the active A, and the drain D of the transistor TR may be formed from the semiconductor pattern.

The first insulating layer 10 may be disposed on the buffer layer BFL. The first insulating layer 10 may cover the semiconductor pattern. The gate G of the transistor TR may be disposed on the first insulating layer 10. The second insulating layer may be disposed on the gate G. The gate G may be a portion of a metal pattern. The gate G may overlap the active A. The gate G may be used as a mask in a process of doping the semiconductor pattern.

The gate G may include titanium (Ti), silver (Ag), an alloy including or consisting of silver (Ag), molybdenum (Mo), an alloy including or consisting of molybdenum (Mo), aluminum (Al), an alloy including or consisting of aluminum (Al), aluminum nitride (AlN), tungsten (W), tungsten nitride (WN), copper (Cu), indium tin oxide (“ITO”), indium zinc oxide (“IZO”), or the like, however, it should not be particularly limited.

The second insulating layer 20 may be disposed on the first insulating layer 10 and may cover the gate G. The transistor TR may further include an upper electrode disposed on the second insulating layer 20 and overlapping the gate G. The third insulating layer 30 may be disposed on the second insulating layer 20. The fourth insulating layer 40 may be disposed on the third insulating layer 30. Each of the first to fourth insulating layers 10 to 40 may be an inorganic layer and/or an organic layer and may have a single-layer or multi-layer structure.

A connection electrode CNE may include a first connection electrode CNE1 and a second connection electrode CNE2 to connect the transistor TR to the light-emitting element OLED. The first connection electrode CNE1 may be disposed on the fourth insulating layer 40 and may be connected to the drain D via a first contact hole CH1 defined through the first, second, third, and fourth insulating layers 10, 20, 30, and 40.

The fifth insulating layer 50 may be disposed on the fourth insulating layer 40. The fifth insulating layer 50 may be an organic layer. The second connection electrode CNE2 may be disposed on the fifth insulating layer 50. The second connection electrode CNE2 may be connected to the first connection electrode CNE1 via a second contact hole CH2 defined through the fifth insulating layer 50.

The sixth insulating layer 60 may be disposed on the second connection electrode CNE2. Each layer from the buffer layer BFL to the sixth insulating layer 60 may be defined as the circuit element layer DP-CL. The sixth insulating layer 60 may be an organic layer. A first electrode AE may be disposed on the sixth insulating layer 60. The first electrode AE may be connected to the second connection electrode CNE2 via a third contact hole CH3 defined through the sixth insulating layer 60. The first electrode AE may be connected to the transistor TR via the first and second connection electrodes CNE1 and CNE2. The pixel definition layer PDL may be disposed on the first electrode AE and the sixth insulating layer 60. An opening PX_OP may be defined through the pixel definition layer PDL to expose a portion of the first electrode AE.

A hole control layer HCL may be disposed on the first electrode AE and the pixel definition layer PDL. The hole control layer HCL may include a hole transport layer and a hole injection layer.

The light-emitting layer EML may be disposed on the hole control layer HCL. The light-emitting layer EML may be disposed in an area corresponding to the opening PX_OP. The light-emitting layer EML may include an organic material and/or an inorganic material. The light-emitting layer EML may generate a light having one of red, green, and blue colors.

An electron control layer ECL may be disposed on the light-emitting layer EML and the hole control layer HCL. The electron control layer ECL may include an electron transport layer and an electron injection layer. The hole control layer HCL and the electron control layer ECL may be commonly disposed in the light-emitting area LA and the non-light-emitting area NLA.

A second electrode CE may be disposed on the electron control layer ECL. The second electrode CE may be commonly disposed over the pixels PX (refer to FIG. 4). A layer in which the light-emitting element OLED is disposed may be also referred to as the display element layer DP-OLED.

The thin film encapsulation layer TFE may be disposed on the second electrode CE to cover the pixel PX (refer to FIG. 4). Although not shown in drawing figures, the thin film encapsulation layer TFE may include a plurality of layers. Some of the layers may include an inorganic insulating layer and may protect the pixel PX (refer to FIG. 4) from moisture and oxygen. Remaining (the other) layers of the layers may include an organic insulating layer and may protect the pixel PX (refer to FIG. 4) from a foreign substance such as dust particles.

A first voltage may be applied to the first electrode AE via the transistor TR, and a second voltage having a level lower than a level of the first voltage may be applied to the second electrode CE. Holes and electrons injected into the light-emitting layer EML may be recombined to generate excitons, and the light-emitting element OLED may emit the light by the excitons that return to a ground state from an excited state.

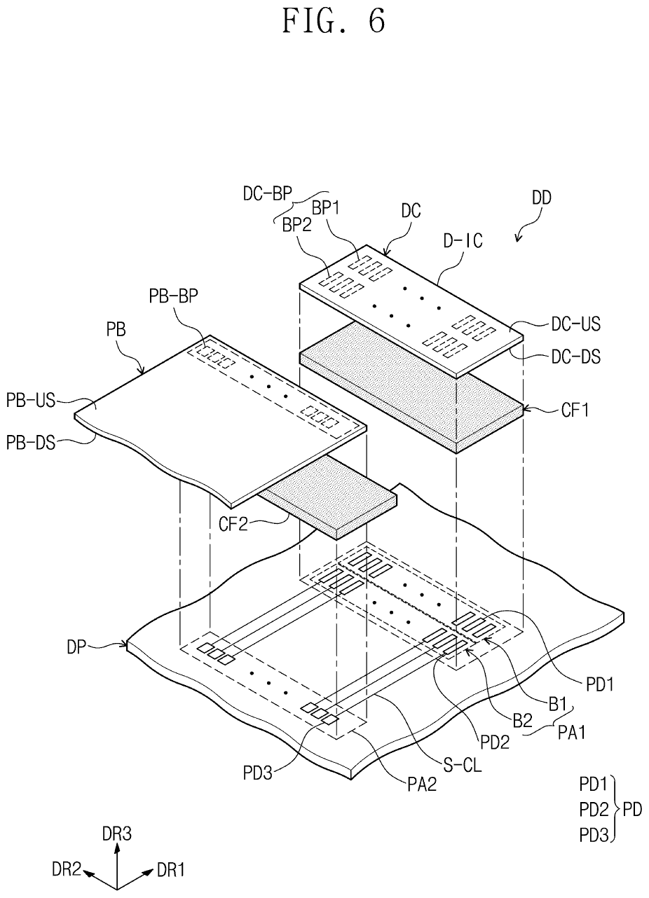

FIG. 6 is an exploded perspective view of an embodiment of the pad areas PA1 and PA2 of the display device DD according to the disclosure. In FIG. 6, the driving chip DC and the circuit board PB are shown as being separated from the display panel DP as an example. Since the first pads PD1, the second pads area PD2, the connection signal lines S-CL, and the third pads PD3 are the same as those of FIG. 4, details thereof will be omitted.

The driving chip DC may be bonded to the first pad area PA1 by a first adhesive layer CF1. The circuit board PB may be bonded to the second pad area PA2 by a second adhesive layer CF2.

In an embodiment of the disclosure, the first adhesive layer CF1 and the second adhesive layer CF2 may include a non-conductive film. That is, the first adhesive layer CF1 and the second adhesive layer CF2 may include a synthetic resin with an adhesive property and may not include conductive balls. Since the synthetic resin does not need to maintain the arrangement of the conductive balls, the synthetic resin may have a relatively low viscosity.

The driving chip DC may include a driving integrated circuit D-IC and chip bump electrodes DC-BP provided in the driving chip DC. The driving integrated circuit D-IC may include an upper surface DC-US and a lower surface DC-DS, and the lower surface DC-DS may face the first and second pads PD1 and PD2. The chip bump electrodes DC-BP may be disposed on the lower surface DC-DS of the driving integrated circuit D-IC.

The chip bump electrodes DC-BP may include first bumps BP1 electrically connected to the first pads PD1, respectively, and second bumps BP2 electrically connected to the second pads PD2, respectively. The first bumps BP1 may be arranged in the second direction DR2, and the second bumps BP2 may be spaced apart from the first bumps BP1 in the first direction DR1 and may be arranged in the second direction DR2.

The driving chip DC may receive first signals from the outside via the second pads PD2 and the second bumps BP2. The driving chip DC may apply second signals, which are generated based on the first signals, to the first pads PD1 via the first bumps BP1. In an embodiment, the driving chip DC may include a data driving circuit. The first signal may be an image signal that is a digital signal provided from the outside, and the second signal may be a data signal that is an analog signal. The driving chip DC may generate an analog voltage corresponding to a grayscale value of the image signal. The data signal may be applied to the pixel PX via the data line DL shown in FIG. 4.

Although not shown in FIG. 6, the first bumps BP1 and the second bumps BP2 may protrude from the lower surface DC-DS of the driving integrated circuit D-IC and may be exposed to the outside. When the first adhesive layer CF1 is cured, the first pads PD1 may be attached to and fixed to the first bumps BP1, and the second pads PD2 may be attached to and fixed to the second bumps BP2.

The circuit board PB may include substrate bumps PB-BP provided in the circuit board PB. The circuit board PB may include an upper surface PB-US and a lower surface PB-DS, and the lower surface PB-DS may face the third pads PD3. The substrate bumps PB-BP may be disposed on the lower surface PB-DS of the circuit board PB. The substrate bumps PB-BP may be electrically connected to the third pads PD3, respectively. The substrate bumps PB-BP may be arranged in the second direction DR2. The circuit board PB may provide image signals, driving voltages, and other control signals to the driving chip DC.

Although not shown in FIG. 6, the substrate bumps PB-BP may protrude from the lower surface PB-DS of the circuit board PB and may be exposed to the outside. When the second adhesive layer CF2 is cured, the third pads PD3 may be attached to and fixed to the substrate bumps PB-BP.

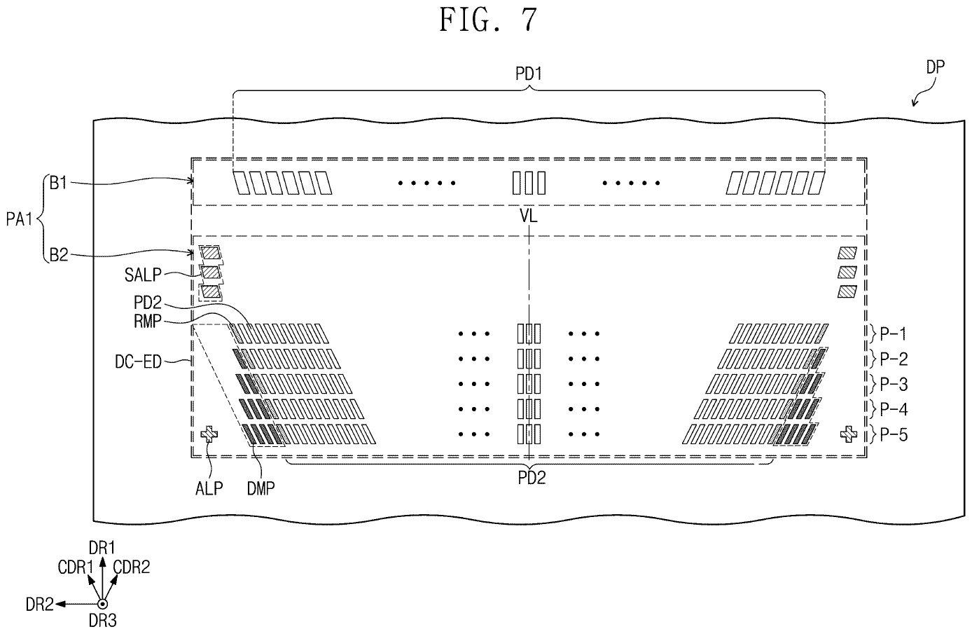

FIG. 7 is an enlarged plan view of an embodiment of the first pad area PA1 shown in FIG. 6 according to the disclosure.

The first pad area PA1 may include the first area B1 in which the first pads PD1 are arranged and the second area B2 in which the second pads PD2 are arranged. Descriptions on the first pad area PA1 with reference to FIG. 7 may be equally applied to the second pad area PA2, and descriptions on the second pads PD2 with reference to FIG. 7 may be equally applied to the first pads PD1 and the third pads PD3. In addition, in the disclosure, the first direction DR1 may be also referred to as a column direction, and the second direction DR2 may be also referred to as a row direction.

Referring to FIG. 7, an edge DC-ED of the driving chip DC (refer to FIG. 6) may define a quadrangular shape when viewed from a plane defined by the first direction DR1 and the second direction DR2. However, the shape of the edge DC-ED of the driving chip in the plan view should not be particularly limited.

The first pad area PA1 may be an area to which the driving chip DC (refer to FIG. 6) is bonded. The first pads PD1 and the second pads PD2 corresponding to the chip bump electrodes DC-BP (refer to FIG. 6) may be arranged in the first pad area PA1. Each of the second pads PD2 may include a plurality of output rows P-1, P-2, P-3, P-4, and P-5 extending in the first direction DR1.

Among the second pads PD2, the second pads PD2 arranged at a left side of a virtual line VL may be inclined at a selected inclination with respect to the virtual line VL. The second pads PD2 arranged at the left side may extend in a first diagonal direction CDR1. Among the second pads PD2, the second pads PD2 arranged at a right side of the virtual line VL may extend in a second diagonal direction CDR2.

In the first pad area PA1, an alignment pad ALP may be placed in an outer area of at least one of the output rows P-1, P-2, P-3, P-4, and P-5. In the illustrated embodiment, two alignment pads ALP each having a cross shape are placed in the outer area of a fifth output row P-5 as an illustrative embodiment. When viewed in the plane, the alignment pads ALP may be disposed between the edge DC-ED of the driving chip and dummy pads DMP placed outside the fifth output row P-5. The alignment pads ALP may correspond to an identification mark or an alignment mark to identify or align a position of the driving chip DC (refer to FIG. 6) in the process of bonding the driving chip DC (refer to FIG. 6) to the display panel DP.

A sub-alignment pad SALP corresponding to a sub-alignment bump of the driving chip DC (refer to FIG. 6) may be disposed in the first pad area PA1. The sub-alignment pad SALP may have the same shape as that of the sub-alignment bump of the driving chip DC (refer to FIG. 6). In cases where the use of an alignment bump bonded to the alignment pad ALP is not possible, the sub-alignment pad SALP may serve as an identification mark or an alignment mark for aligning the driving chip DC (refer to FIG. 6) with the display panel DP in the process of bonding the driving chip DC (refer to FIG. 6) and the display panel DP or for determining whether the alignment between the driving chip DC (refer to FIG. 6) and the display panel DP is appropriate in the process of inspecting the alignment of the driving chip DC (refer to FIG. 6).

A bonding resistance monitoring pad RMP may be disposed in the first pad area PA1 to be parallel to the second pads PD2. The bonding resistance monitoring pad RMP may refer to a pad to measure a bonding resistance in the bonding process. The bonding resistance monitoring pad RMP may be placed in an outer area of at least one of the output rows P-1, P-2, P-3, P-4, and P-5 of the second pads PD2, however, the disclosure should not be limited thereto or thereby. In the illustrated embodiment, multiple bonding resistance monitoring pads RMP may be placed in outer areas of the first, second, third, fourth, and fifth output rows P-1, P-2, P-3, P-4, and P-5 of the second pads PD2, respectively, and may have the same shape as that of the second pads PD2.

The dummy pad DMP may be disposed in the first pad area PA1 to be parallel to the second pads PD2. The second pads PD2 may refer to pads to which the data line DL (refer to FIG. 4) is connected, and the dummy pad DMP may refer to a pad which is electrically isolated. The dummy pad DMP may be spaced apart from the second pads PD2. The dummy pad DMP may correspond to a dummy bump of the driving chip DC (refer to FIG. 6) and may be disposed at an outermost position of the first pad area PA1. The dummy pad DMP may be disposed between the bonding resistance monitoring pad RMP and the edge DC-ED of the driving chip in at least one row of the output rows P-1, P-2, P-3, P-4, and P-5. In the illustrated embodiment, the dummy pad DMP may be disposed at the second, third, fourth, and fifth output rows P-2, P-3, P-4, and P-5, but it should not be limited thereto or thereby.

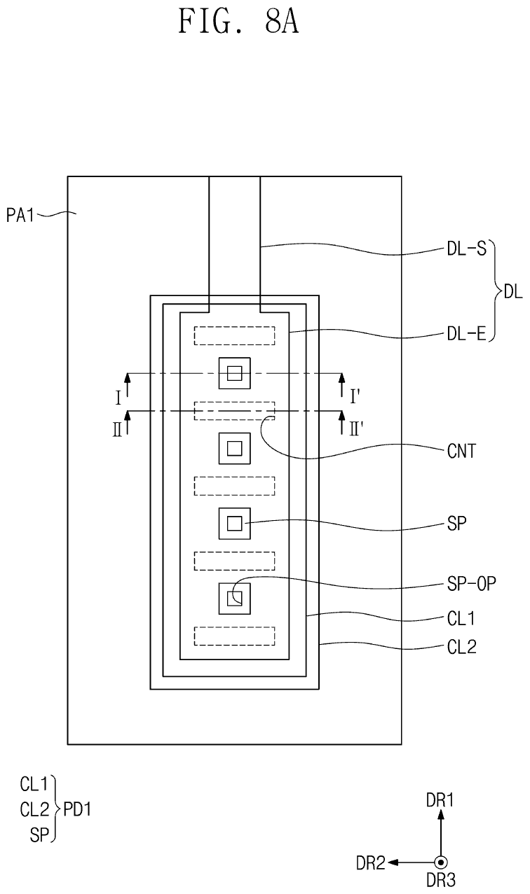

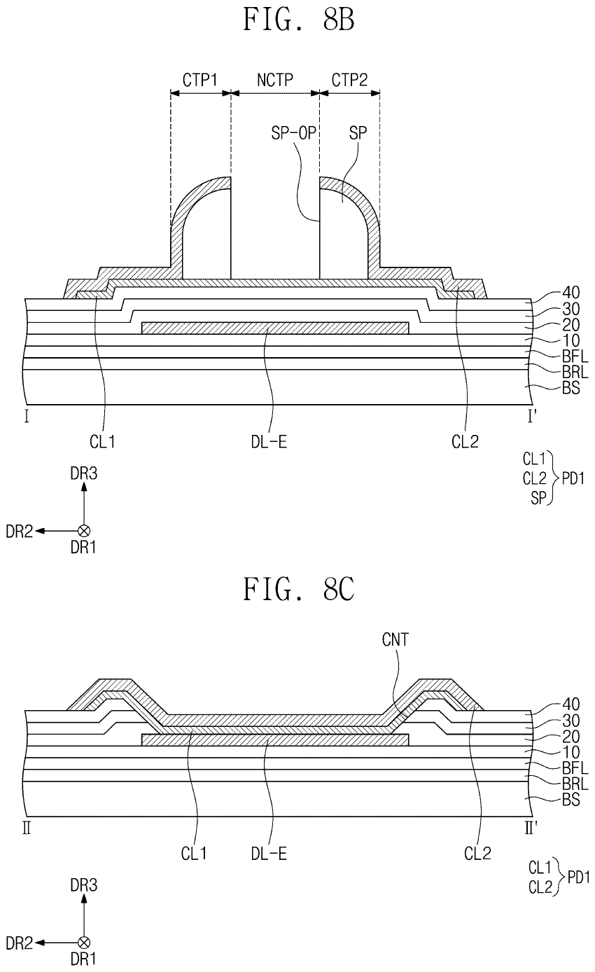

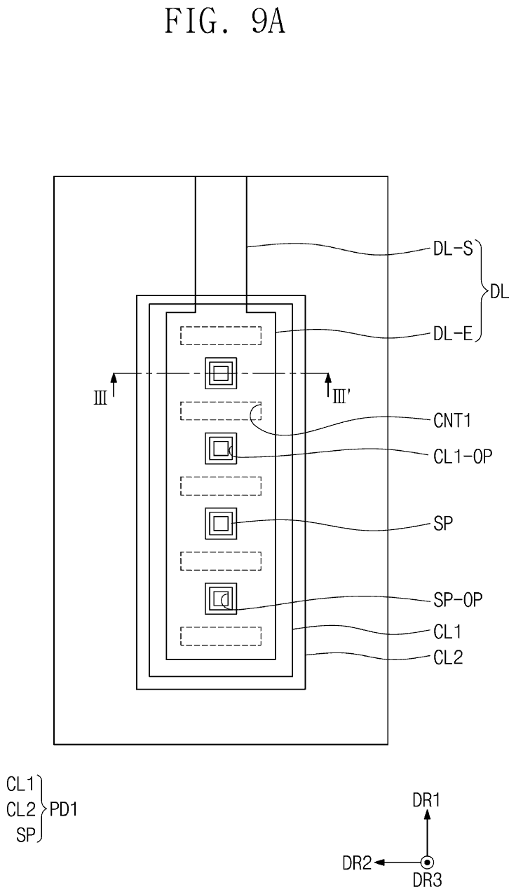

FIG. 8A is an enlarged plan view of an embodiment of the first pad PD1 according to the disclosure, and FIGS. 8B and 8C are cross-sectional views of the first pad PD1. FIG. 8B is a cross-sectional view taken along line I-I′ of FIG. 8A, and FIG. 8C is a cross-sectional view taken along line II-II′ of FIG. 8A.

FIG. 8A shows the first pad PD1 disposed in the first pad area PA1 as an illustrative embodiment, and the second pad PD2 and the third pad PD3 may have the same structure and shape as those of the first pad PD1. In addition, the data line DL is shown in an embodiment of the signal line in FIG. 8, however, the signal line should not be limited to the data line DL, and remaining (the other) signal lines of the signal lines SGL shown in FIG. 4 may be the signal line of FIG. 8A.

Referring to FIGS. 4 and 8A, the data line DL may include the line part DL-S and an end part DL-E. DL-S may be connected to a corresponding pixel among the pixels PX and may extend in the first direction DR1. FIG. 8A shows the end part DL-E and the line part DL-S, which have different widths, as an illustrative embodiment, however, the disclosure should not be limited thereto or thereby. In the illustrated embodiment, the width may indicate a length or width in the second direction DR2 of the end part DL-E or the line part DL-S.

Hereinafter, the first pad PD1 will be described based on the first pad area PA1 where the data line DL is disposed. The descriptions on the first pad area PA1 may be applied to the second pad area PA2 (refer to FIG. 6) except that the connection signal line S-CL (refer to FIG. 6) is arranged in place of the data line DL.

The end part DL-E of the data line DL may extend from an end of the line part DL-S to the first direction DR1. Although not shown in drawing figures, the end part DL-E and the line part DL-S of the data line DL may be connected to each other while being disposed at different layers.

Referring to FIG. 8A, the first pad PD1 may include a first conductive pattern CL1 connected to the end part DL-E of the signal line, a second conductive pattern CL2 connected to the first conductive pattern CL1, and an insulating pattern SP.

When viewed in the plane, the insulating pattern SP may overlap the first conductive pattern CL1 and the second conductive pattern CL2. When viewed in the plane, the insulating pattern SP may be disposed inside the first conductive pattern CL1 and inside the second conductive pattern CL2.

As shown in FIG. 8A, the insulating pattern SP may be provided in plural, and the insulating patterns SP may be arranged in the first direction DR1. FIG. 8A shows the insulating patterns SP having a square shape in the plan view as an illustrative embodiment, however, the disclosure should not be limited thereto or thereby. The shape of the insulating patterns SP in the plan view may be changed to a polygonal shape such as a quadrangular shape, e.g., rectangular shape, a circular shape, an oval shape, or the like. In addition, the shapes of the insulating patterns SP should not be limited to being identical to each other.

An opening SP-OP may be defined through the insulating pattern SP and may overlap the end part DL-E of the signal line. FIG. 8A shows a structure in which the opening SP-OP is defined through each of the insulating patterns SP as an illustrative embodiment, however, the disclosure should not be limited thereto or thereby. In addition, the opening SP-OP may have a square shape in the plan view, however, the shape of the opening SP-OP may be changed to a polygonal shape such as a quadrangular shape, e.g., rectangular shape, a circular shape, an oval shape, or the like in the plan view. In addition, the shapes of the opening SP-OP should not be limited to being identical to each other.

When viewed in the plane, a contact hole CNT may be provided in plural, and the contact holes CNT may be arranged in the first direction DR1. In an embodiment, five contact holes CNT may be disposed between the insulating patterns SP. Each of the insulating patterns SP may be disposed between two contact holes CNT next (adjacent) to each other among the contact holes CNT. When viewed in the plane, the contact holes CNT may be disposed inside the first conductive pattern CL1 and the second conductive patterns CL2.

FIG. 8B is a cross-sectional view taken along line I-I′ of an embodiment of FIG. 8A according to the disclosure. The base layer BS, the barrier layer BRL, the buffer layer BFL, the first insulating layer 10, the second insulating layer 20, the third insulating layer 30, and the fourth insulating layer 40 shown in FIG. 8B are the same as those described with reference to FIG. 5, and thus, detailed descriptions thereof will be omitted.

Referring to FIGS. 8B and 8C, the end part DL-E may be disposed at the same layer as the gate G shown in FIG. 5. The end part DL-E may be formed through the same process as the gate G. The end part DL-E may include the same material as that of the gate G. However, the position of the end part DL-E should not be limited thereto or thereby. The second insulating layer 20 may be disposed on the end part DL-E to cover the end part DL-E. The third insulating layer 30 may be disposed on the second insulating layer 20, and the fourth insulating layer 40 may be disposed on the third insulating layer 30.

The data line DL may be disposed at a single layer and may have an integral shape, but it should not be limited thereto or thereby. One data line DL may include multiple parts disposed at different layers. In an embodiment, the line part DL-S may include two or more parts, for example.

The first conductive pattern CL1 may be disposed on the end part DL-E. The first conductive pattern CL1 may be disposed directly on the end part DL-E, and thus, the first conductive pattern CL1 and the end part DL-E may be electrically connected to each other. Referring to FIG. 8C, the first conductive pattern CL1 may contact the end part DL-E through the contact hole CNT. In addition, the first conductive pattern CL1 may be disposed on the fourth insulating layer 40.

The second conductive pattern CL2 may be disposed on the first conductive pattern CL1. A portion of the second conductive pattern CL2, which does not overlap the insulating pattern SP, may contact the first conductive pattern CL1, and thus, the first conductive pattern CL1 may be electrically connected to the second conductive pattern CL2.

In an embodiment, the first conductive pattern CL1 may be formed through the same process as the first connection electrode CNE1 described with reference to FIG. 5, and the second conductive pattern CL2 may be formed through the same process as the second connection electrode CNE2 described with reference to FIG. 5. The first conductive pattern CL1 may include the same material as that of the first connection electrode CNE1 (refer to FIG. 5), and the second conductive pattern CL2 may include the same material as that of the second connection electrode CNE2 (refer to FIG. 5). However, the disclosure should not be limited thereto or thereby, and combinations of connection electrodes formed through the same process as the first and second conductive patterns CL1 and CL2 may be selected in various ways depending on the stack structure of the circuit element layer DP-CL (refer to FIG. 5) as long as the first and second conductive patterns CL1 and CL2 are provided at different layers from each other.

When viewed in the plane, the second conductive pattern CL2 may have an area greater than that of the first conductive pattern CL1, and an edge of the second conductive pattern CL2 may be disposed outside an edge of the first conductive pattern CL1 and may cover the edge of the first conductive pattern CL1, however, the disclosure should not be limited thereto or thereby. The second conductive pattern CL2 may have substantially the same area as the first conductive pattern CL1, and the edge of the second conductive pattern CL2 may be substantially aligned with the edge of the first conductive pattern CL1.

Referring to FIG. 8B, the insulating pattern SP may be disposed between the end part DL-E of the signal line and the second conductive pattern CL2. The insulating pattern SP may be disposed on the first conductive pattern CL1 and may be covered by the second conductive pattern CL2. That is, the second conductive pattern CL2 may cover an upper surface of the insulating pattern SP.

In FIG. 8B, a lower surface of the insulating pattern SP may be defined as a surface where the insulating pattern SP contacts the first conductive pattern CL1, and the upper surface of the insulating pattern SP may be defined as a remaining surface except the lower surface of the insulating pattern SP and a side surface corresponding to the opening SP-OP. The upper surface of the insulating pattern SP may contact the second conductive pattern CL2.

The insulating pattern SP may have a dome shape when viewed in a cross-section. However, the disclosure should not be limited thereto or thereby, and the insulating pattern SP may have a cylindrical shape, a trapezoidal shape, a quadrangular shape, e.g., rectangular shape, or an inverted trapezoidal shape when viewed in the cross-section.

The insulating pattern SP may include a polymer. The insulating pattern SP may include a thermosetting polymer, however, the disclosure should not be limited thereto or thereby. In an embodiment, the insulating pattern SP may include a thermoplastic polymer.

The insulating pattern SP may be formed through the same process as the fifth insulating layer 50 (refer to FIG. 5), however, the disclosure should not be limited thereto or thereby. As described later, combinations of the insulating layer formed through the same process as the insulating pattern SP may be selected in various ways depending on the stack structure of the circuit element layer DP-CL (refer to FIG. 5), and thus, the insulating layer formed through the same process as the insulating pattern SP may also be selected in various ways.

As shown in FIG. 8B, the opening SP-OP may be defined through the insulating pattern SP to overlap a portion of the end part DL-E of the signal line. That is, an opening corresponding to the opening SP-OP of the insulating pattern may be defined through the second conductive pattern CL2 covering the insulating pattern SP. FIG. 8B shows the opening SP-OP defined by removing a center portion in the second direction DR2 of the insulating pattern SP, however, the position of the opening SP-OP should not be limited thereto or thereby. In addition, in the plan view, the opening SP-OP of FIG. 8B may have the quadrangular shape, however, the opening SP-OP may have various shapes without being limited to the quadrangular shape.

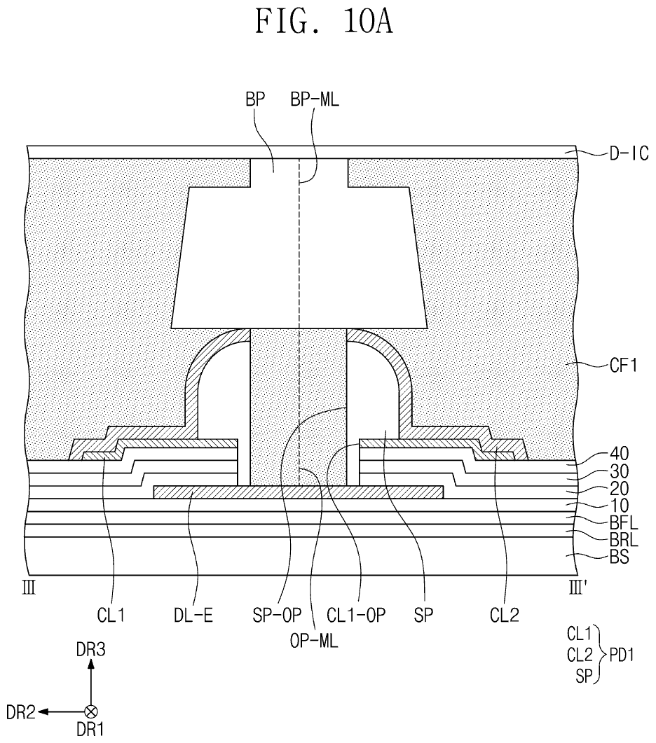

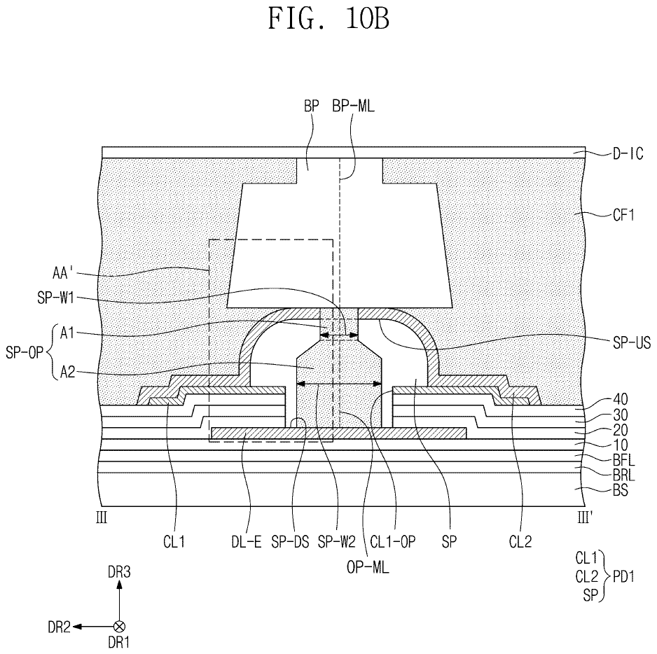

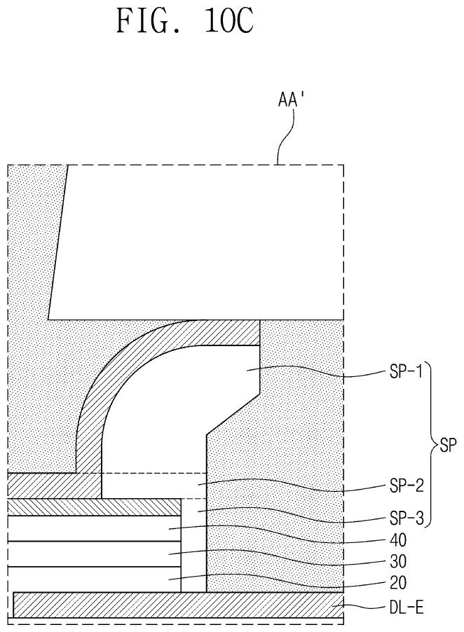

The second conductive pattern CL2 covering the insulating pattern SP may include a first contact part CTP1 and a second contact part CTP2, which contact a bump BP (refer to FIG. 10A) described later. A non-contact part NCTP that is not in contact with the bump BP (refer to FIG. 10A) may be disposed between the first contact part CTP1 and the second contact part CTP2 and may correspond to the opening SP-OP.

Referring to FIG. 8C, the contact hole CNT may be defined through the second to fourth insulating layers 20 to 40. The contact hole CNT may penetrate through the second to fourth insulating layers 20 to 40. A portion of an upper surface of the end part DL-E of the signal line may be exposed to the outside through the contact hole CNT, and the first conductive pattern CL1 and the second conductive pattern CL2 may extend along inner side surfaces of the second to fourth insulating layers 20 to 40, which define the contact hole CNT, and may extend along the exposed upper surface of the end part DL-E.

The end part DL-E of the data line DL may extend from the end of the line part DL-S to the first direction DR1. Although not shown in drawing figures, the end part DL-E and the line part DL-S of the data line DL may be connected to each other while being disposed at different layers.

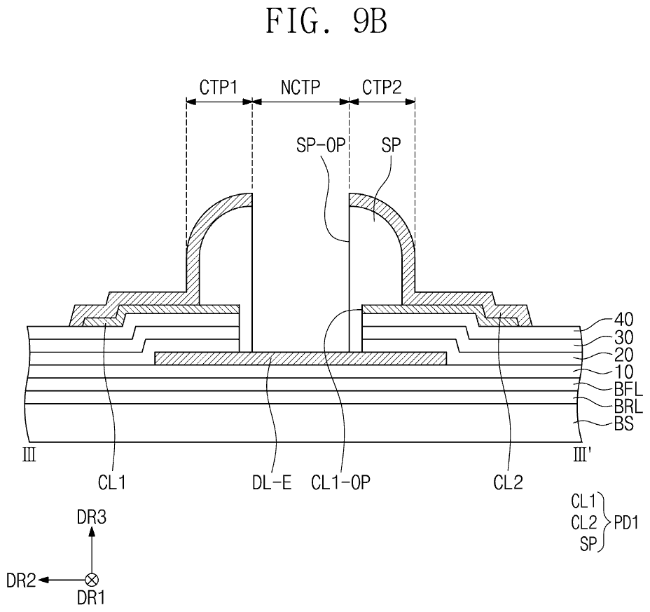

FIG. 9A is an enlarged plan view of an embodiment of a first pad PD1 according to the disclosure, and FIG. 9B is a cross-sectional view taken along line III-III′ of FIG. 9A. In FIGS. 9A and 9B, detailed descriptions on the same elements as those described with reference to FIGS. 8A to 8C will be omitted.

Referring to FIG. 9A, in the plan view, an opening CL1-OP may be defined through a first conductive pattern CL1 to correspond to an opening SP-OP of an insulating pattern SP. When viewed in the plane, the opening CL1-OP of the first conductive pattern may be defined outside the opening SP-OP of the insulating pattern and may be defined inside the insulating pattern SP. The opening CL1-OP of the first conductive pattern may have a square shape in the plan view, however, it should not be limited thereto or thereby. In an embodiment, the opening CL1-OP of the first conductive pattern may have various shapes, such as a circular shape, an oval shape, a quadrangular shape, e.g., rectangular shape, etc. The openings CL1-OP of multiple first conductive patterns may correspond to the openings SP-OP of multiple insulating patterns in a one-to-one correspondence and may overlap an end part DL-E.

Referring to FIG. 9B, an edge of the first conductive pattern CL1 in the second direction DR2 may be covered by the insulating pattern SP when viewed in the cross-section. As the opening CL1-OP is defined through the first conductive pattern, an upper surface of the end part DL-E may be exposed. As shown in FIG. 9B, a width of the opening CL1-OP of the first conductive pattern may be greater than a width of the opening SP-OP of the insulating pattern, however, it should not be limited thereto or thereby. That is, the width of the opening CL1-OP of the first conductive pattern may be the same as the width of the opening SP-OP of the insulating pattern.

Referring to FIG. 9B, when viewed in the cross-section, an opening may be defined through second to fourth insulating layers 20 to 40 covering the end part DL-E of a data line to correspond to the opening SP-OP of the insulating pattern. In an embodiment, a portion of the insulating pattern SP may be disposed in the opening of the second to fourth insulating layers 20 to 40. In addition, the portion of the insulating pattern SP may contact inner side surfaces of the second to fourth insulating layers 20 to 40, and the insulating pattern SP may be directly in contact with the end part DL-E.

The insulating pattern SP may be formed deep enough to contact the end part DL-E in the third direction DR3. In addition, the opening SP-OP of the insulating pattern may also be defined deep enough to expose the upper surface of the end part DL-E. Accordingly, during a bonding process between the first pad PD1 and the bump (BP, refer to FIG. 10A) described later, a protrusion of the insulating patterns SP or a bent portion of the insulating pattern SP may be more easily formed toward a center of the bump.

FIG. 10A is a cross-sectional view taken along line III-III′ of FIG. 9A before an embodiment of the first pad PD1 and the bump BP are bonded according to the disclosure, and FIG. 10B is a cross-sectional view taken along line III-III′ of FIG. 9A after an embodiment of the first pad PD1 and the bump BP are bonded according to the disclosure. In FIGS. 10A and 10B, the same reference numerals denote the same elements in FIGS. 9A and 9B, and thus, detailed descriptions of the same elements will be omitted.

FIG. 10A shows the driving integrated circuit D-IC as the electronic component, however, the disclosure should not be limited thereto or thereby. Referring to FIG. 10A, a portion of the second conductive pattern CL2, which overlaps the insulating pattern SP, may contact the bump BP of the driving integrated circuit D-IC. Accordingly, the bump BP may be electrically connected to the second conductive pattern CL2.

Although not shown in drawing figures, the second conductive pattern CL2 may include a first layer, a second layer, and a third layer, which are sequentially stacked. The second layer may have a thickness greater than a thickness of the first layer. The third layer may have a thickness smaller than the thickness of the second layer. The second layer may have a conductivity higher than a conductivity of the first layer and the third layer. The second layer may include a material having a conductivity higher than a conductivity of a material included in the first layer and the third layer. The first layer and the third layer may include the same material as each other. The second layer may include a material different from the material included in the first layer and the third layer. In an embodiment, the first layer and the third layer may include titanium (Ti), and the second layer may include aluminum (Al). Since a pressure is concentrated at an edge part of the second conductive pattern CL2, which contacts the bump BP, cracks may occur in the third layer including titanium (Ti). Accordingly, the second layer including aluminum (Al) may contact the bump BP. Since the second layer may be covered by the third layer, the second layer may be prevented from being directly in contact with the first adhesive layer CF1. Therefore, a surface of the second layer may be prevented from being oxidized, and thus, the bonding resistance may be stable.

Since the second conductive pattern CL2 is electrically connected to the first conductive pattern CL1 and the end part DL-E of the data line, the bump BP, the first pad PD1, and the end part DL-E of the data line may be electrically connected to each other.

The bump BP may be attached to the first pad PD1 by the first adhesive layer CF1. The first adhesive layer CF1 may contact the first pad PD1 and the bump BP, and the driving integrated circuit D-IC may be bonded to the first pad PD1 by the bonding pressure in the third direction DR3.

Since the first adhesive layer CF1 does not include a conductive material, such as a nano-conductive particle or a conductive ball, even when the signal pads are densely arranged, it is possible to prevent short circuit defects and/or poor conduction that occur when the conductive material is not disposed between the signal pad and the bump BP. Accordingly, the signal pads may be with a fine pitch, which may be advantageous for implementing high-resolution panels.

In the illustrated embodiment, the center BP-ML of the bump BP may correspond to a center OP-ML of the opening SP-OP of the insulating pattern. That is, the second conductive pattern CL2 may be bonded to the bump BP after a center portion of the insulating pattern SP is removed. Accordingly, a portion of the insulating pattern SP may be easily formed as the bent portion toward the center OP-ML of the opening SP-OP of the insulating pattern SP in the bonding process described later.

As shown in FIG. 10B, the bonding pressure may be applied to the bump BP and the first pad PD1 in the third direction DR3 when the bump BP and the first pad PD1 are bonded to each other. As the second conductive pattern CL2 contacts the bump BP in the bonding process, the insulating pattern SP may be compressed. The insulating pattern SP may include a material with lower hardness than a hardness of the second conductive pattern CL2. Accordingly, the insulating pattern SP disposed under the second conductive pattern CL2 may be pressed due to the bonding pressure in the bonding process. As the insulating pattern SP disposed under the second conductive pattern CL2, which contacts the bump BP, is pressed, a portion of the insulating pattern SP may be pressed toward the center BP-ML of the bump BP. That is, as the opening SP-OP is defined through the insulating pattern, the portion of the insulating pattern SP may protrude toward the center BP-ML of the bump.

In an embodiment of the disclosure, the first adhesive layer CF1 may be filled in the opening SP-OP of the insulating pattern. When a stress is applied in the third direction DR3, the first adhesive layer CF1 may prevent the insulating pattern SP from moving to a direction in which the stress is applied after the bonding process. Accordingly, even when the stress is applied to the insulating pattern SP, the contact between the first pad PD1 and the bump BP may be maintained, and electrical connection characteristics between the first pad PD1 and the bump BP may be improved.

As shown in FIG. 10B, an upper surface SP-US of the insulating pattern may refer to a surface that contacts the second conductive pattern CL2, and a lower surface SP-DS of the insulating pattern may refer to a surface that contacts the end part DL-E. However, the disclosure should not be limited thereto or thereby, the upper surface SP-US of the insulating pattern may refer to an uppermost surface in the third direction DR3, and the lower surface SP-DS of the insulating pattern may refer to a lowermost surface in the third direction DR3.

A width SP-W1 of the opening SP-OP measured at the upper surface SP-US of the insulating pattern and a width SP-W2 of the opening SP-OP measured at the lower surface SP-DS of the insulating pattern may indicate a length in the second direction DR2. As the bump BP is bonded, the portion of the insulating pattern may be pressed, and the width SP-W1 of the opening SP-OP measured at the upper surface SP-US of the insulating pattern may be smaller than the width SP-W2 of the opening SP-OP measured at the lower surface SP-DS of the insulating pattern.

Referring to FIG. 10B, the opening SP-OP of the insulating pattern may include a first area A1 and a second area A2 under the first area A1. The first area A1 of the opening SP-OP of the insulating pattern may refer to an imaginary area between the portions of the insulating pattern SP, which protrude toward the center BP-ML of the bump BP. The second area A2 may refer to an imaginary area defined under the first area A1 in the third direction DR3. The width SP-W1 of the first area A1 may be smaller than the width SP-W2 of the second area A2. In an embodiment, when viewed in the cross-section, a diameter in the second direction DR2 of the first area A1 of the opening SP-OP of the insulating pattern may be smaller than a diameter in the second direction DR2 of the second area A2 of the opening SP-OP of the insulating pattern. That is, the opening SP-OP of the insulating pattern may have a bottle shape in the cross-section, where a diameter of a neck portion is narrow.

However, the disclosure should not be limited thereto or thereby, and as the first pad PD1 is bonded to the bump BP, the insulating pattern SP may have a shape recessed or inclined toward the center OP-ML of the opening SP-OP of the insulating pattern.

FIG. 10C is an enlarged cross-sectional view of an area AA′ of FIG. 10B. As shown in FIG. 10C, the insulating pattern SP may include a first portion SP-1 next (adjacent) to the bump and a second portion SP-2 disposed under the first portion SP-1. The first portion SP-1 of the insulating pattern may protrude further toward the center BP-ML (refer to FIG. 10B) of the bump BP than the second portion SP-2. In addition, the insulating pattern may further include a third portion SP-3 disposed under the second portion SP-2 and being in contact with the end part DL-E of the data line. The third portion SP-3 may also contact the first conductive pattern CL1 (refer to FIG. 10B) and the insulating layers 20, 30, and 40.

When evaluating reliability under relatively high temperature and relatively high humidity conditions, stress may occur in the first pad PD1 in the third direction DR3, and thus, a bonding gap where the contact between the bump BP and the first pad PD1 tends to separate may increase. Referring to FIGS. 10A to 10C, the portion of the insulating pattern SP according to the disclosure may protrude toward the center BP-ML of the bump in the bonding process, and the stress may be distributed through the protruded portion. Accordingly, the first pad PD1 including the insulating pattern SP may be prevented from moving in the direction of the stress, and thus, the contact between the first pad PD1 and the bump BP may be maintained. That is, as the opening SP-OP is defined through the insulating pattern and the portion of the insulating pattern SP is inclined in the bonding process, an anchoring may be formed. Furthermore, as the contact is maintained, the reliability and stability of the bonding process may be improved, and the bonding resistance may be reduced.

In addition, referring to FIGS. 7 and 10A to 10C, when the driving chip DC (refer to FIG. 6) is bonded to the first pad area PA1, the stress may be concentrated at the pads corresponding to the column next (adjacent) to the edge DC-ED of the driving chip among the output rows P-1, P-2, P-3, P-4, and P-5 of the second pads PD2. Since a minute bonding gap occurs between the driving chip DC (refer to FIG. 6) and the pads in the third direction DR3 when the stress is concentrated, the stress may be relieved by applying the pad including the insulating pattern SP through which the opening SP-OP is defined. However, the disclosure should not be limited thereto or thereby. As shown in FIG. 7, the pads including the insulating pattern SP through which the opening SP-OP is defined may be applied to the entirety of the first pad area PA1 and may be applied exclusively to the dummy pad DMP or the bonding resistance monitoring pad RMP.

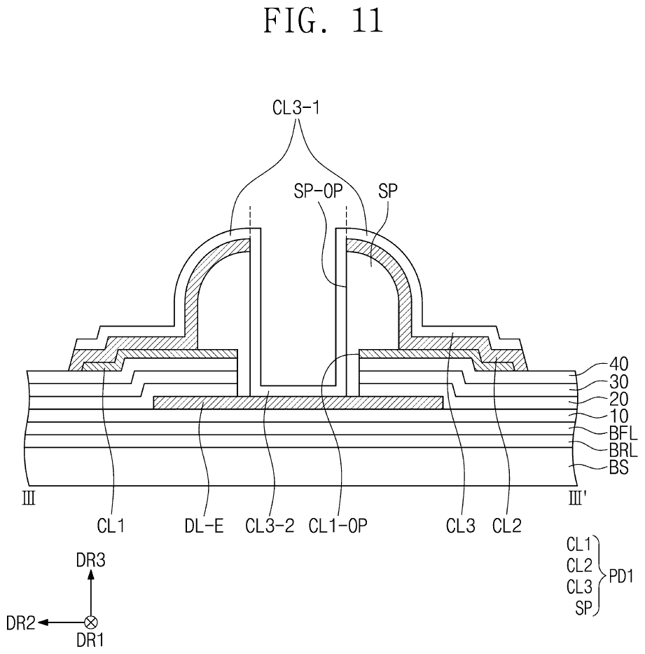

FIG. 11 is a cross-sectional view of an embodiment of a pad according to the disclosure. As shown in FIG. 11, a first pad PD1 may further include a third conductive pattern CL3. The third conductive pattern CL3 may include a first portion CL3-1 disposed on a second conductive pattern CL2 and a second portion CL3-2 disposed inside an opening SP-OP of an insulating pattern. As the first pad PD1 further includes the third conductive pattern CL3, a contact area between the first pad PD1 and a bump (refer to BP of FIG. 10A) may increase in a bonding process, and electrical characteristics may be improved.

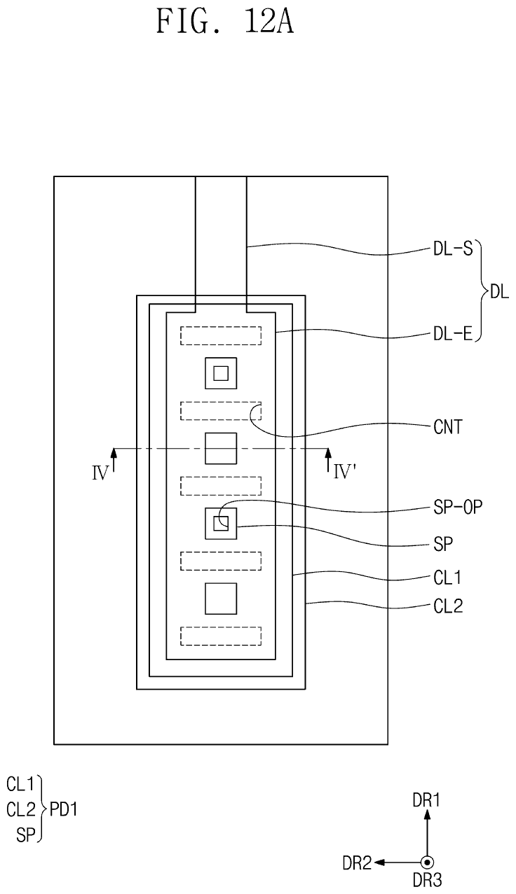

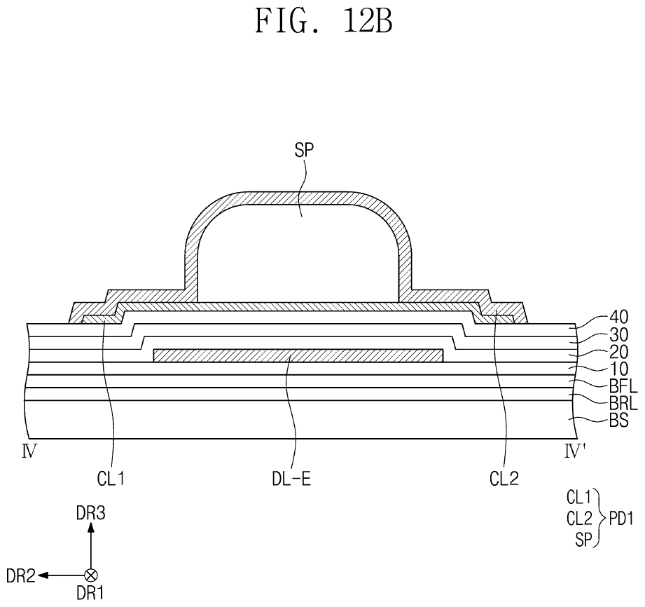

FIG. 12A is a plan view of an embodiment of a pad according to the disclosure, and FIG. 12B is a cross-sectional view taken along line IV-IV′ of FIG. 12A.

As shown in FIG. 12A, some of multiple insulating patterns SP may not be provided with an opening SP-OP. FIG. 12B shows a cross-section of the insulating pattern SP that is not provided with the opening as shown in FIG. 12A. The insulating pattern SP may be disposed between a second conductive pattern CL2 and a first conductive pattern CL1, and the second conductive pattern CL2 may cover the insulating pattern SP.

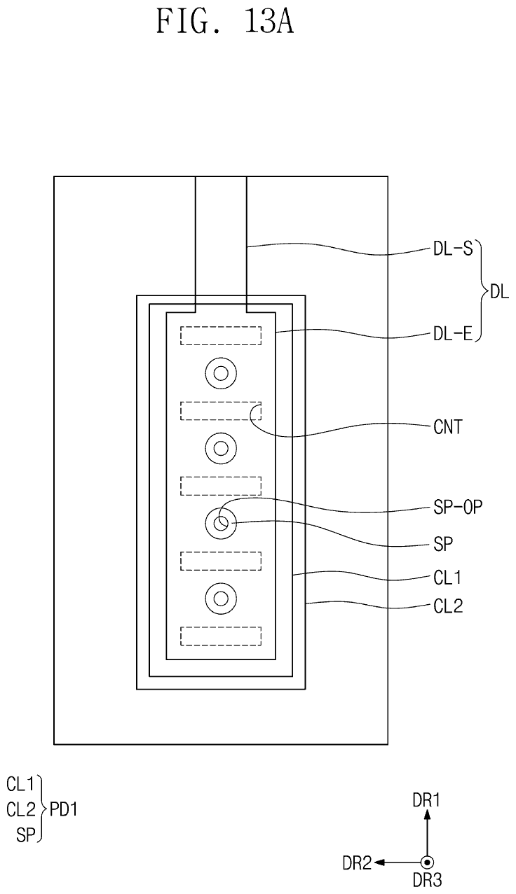

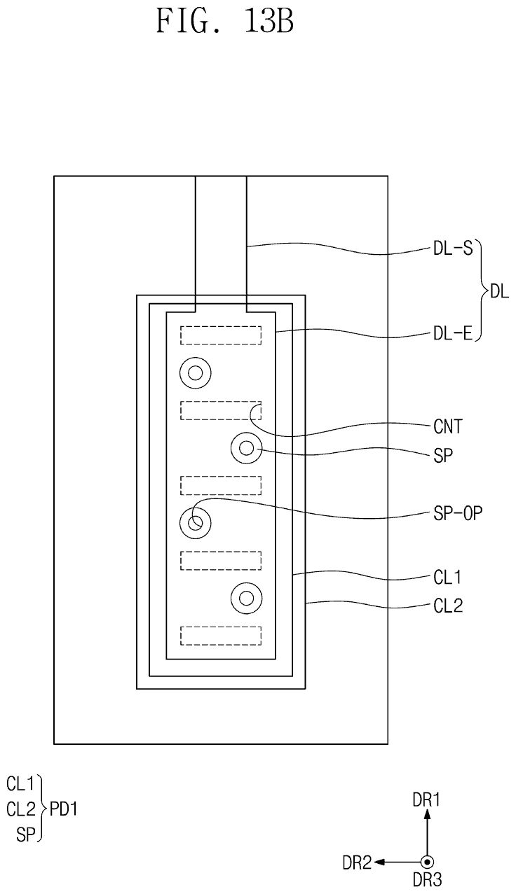

FIGS. 13A and 13B are plan views of an embodiment of pads according to the disclosure.

Referring to FIG. 13A, a shape of an insulating pattern SP should not be limited to a polygonal shape such as a square shape, a quadrangular, e.g., rectangular shape, etc., and may have a circular shape. A shape of an opening SP-OP of the insulating pattern should not be limited to a polygonal shape such as a square shape, a quadrangular, e.g., rectangular shape, etc., and may have a circular shape. The shapes of the openings SP-OP in multiple insulating patterns do not necessarily need to be identical to each other.

Referring to FIG. 13B, multiple insulating patterns SP may be arranged in the first direction DR1 but may be staggered in the second direction DR2. That is, the insulating patterns may be arranged in a zigzag pattern.

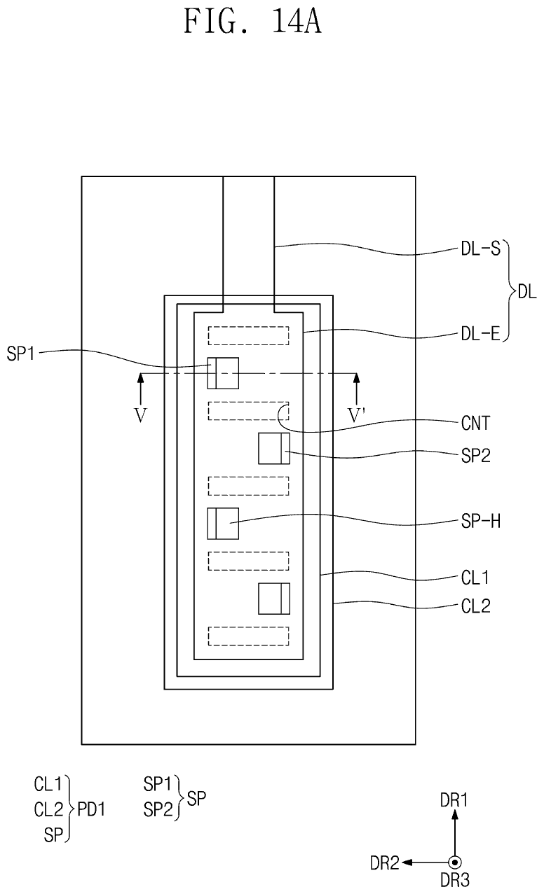

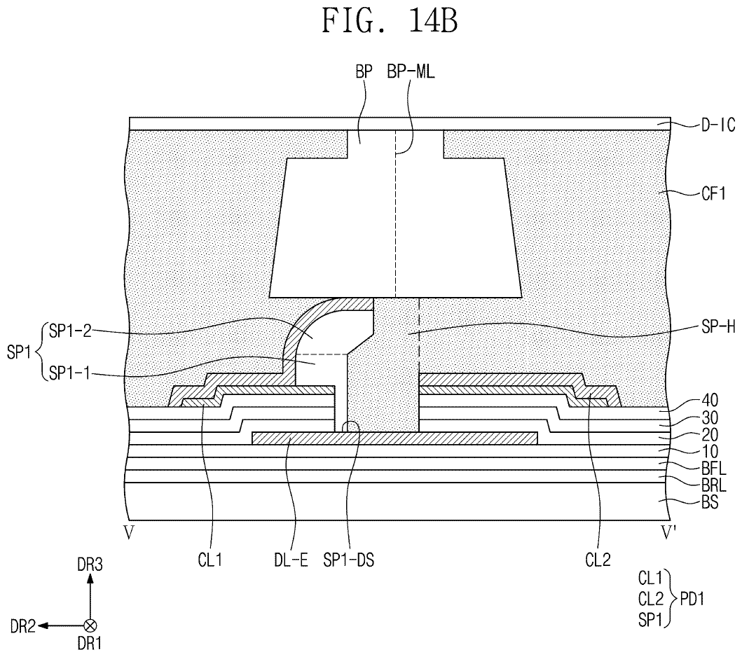

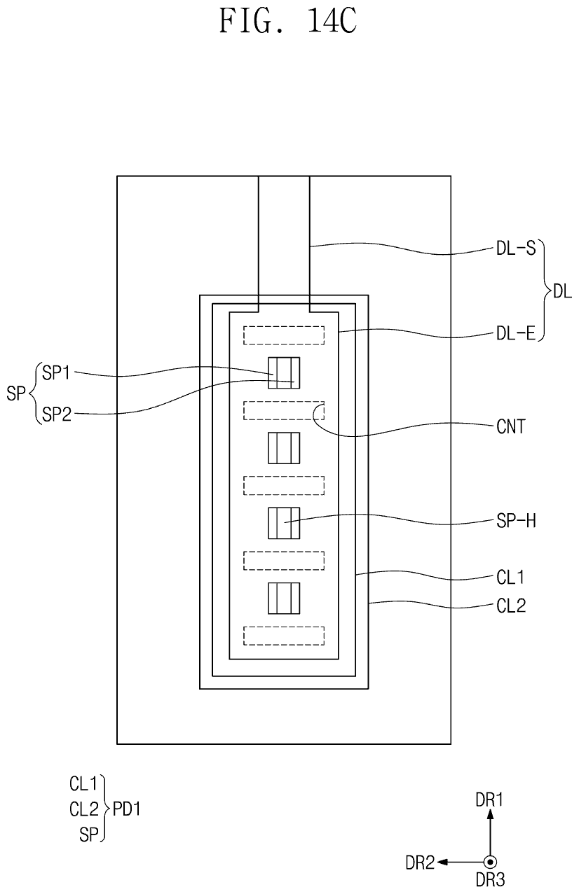

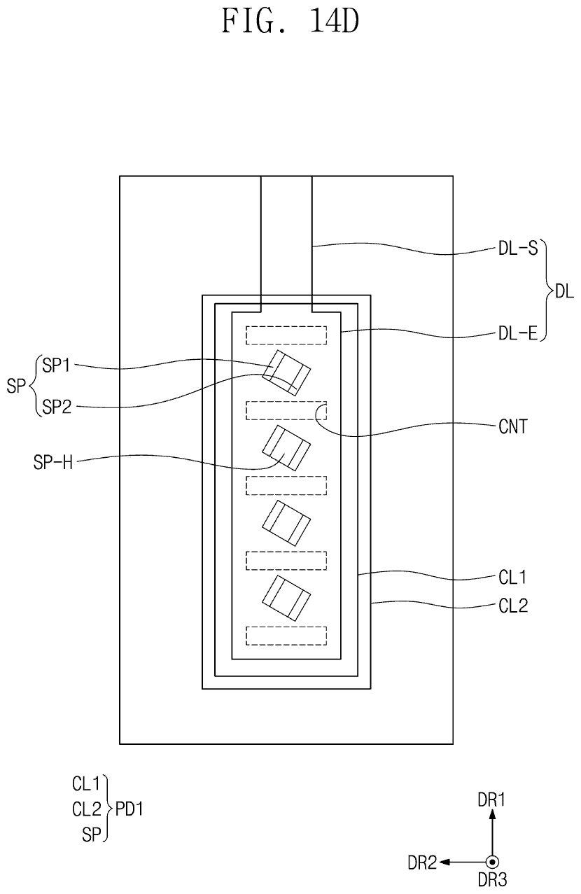

FIG. 14A is a plan view of an embodiment of a pad according to the disclosure, and FIG. 14B is a cross-sectional view taken along line V-V′ of FIG. 14A. FIGS. 14C and 14D are plan views of an embodiment of pads according to the disclosure.

Referring to FIG. 14A, an insulating pattern SP may be provided in plural, and the insulating patterns SP may include first insulating patterns SP1 and second insulating patterns SP2, which are arranged in a zigzag pattern in the second direction DR2 intersecting the first direction. The insulating patterns SP may be arranged in the first direction DR1. In addition, one side surface of the first insulating patterns SP1 or the second insulating patterns SP2 may be removed to form a hole SP-H through the insulating pattern. Accordingly, the holes SP-H of the first insulating patterns SP1 and the second insulating patterns SP2 may also be arranged in a zigzag pattern in the second direction DR2.

Referring to FIG. 14B, the first insulating pattern SP1 may be disposed between an end part DL-E of a data line and a second conductive pattern CL2. In an embodiment, a lower surface SP1-DS of the first insulating pattern SP1 may contact the end part DL-E. In addition, the first insulating pattern SP1 may include a first portion SP1-1 and a second portion SP1-2 disposed on the first portion SP1-1. At least a portion of the second portion SP1-2 may protrude from the first portion SP1-1 toward a center BP-ML of a bump.

When viewed in the cross-section, a width of the second portion SP1-2 of the insulating pattern may be greater than a width of the first portion SP1-1. That is, since the second portion SP1-2 of the insulating pattern is bonded to the bump BP and protrudes toward the center BP-ML of the bump, the second portion SP1-2 may have the width greater than that of the first portion SP1-1.

When viewed in the cross-section, the first portion SP1-1 of the insulating pattern may extend to contact one side surface of a first conductive pattern CL1. In addition, the first portion SP1-1 of the insulating pattern may extend to contact one side surfaces of second to fourth insulating layers 20 to 40. Accordingly, the hole SP-H of the insulating pattern may be formed to correspond to the first conductive pattern CL1 and the second to fourth insulating layers 20 to 40. That is, as the one side surface of the insulating pattern SP is removed, the insulating pattern SP may include the second portion SP1-2 protruding toward the center BP-ML of the bump when the first pad PD1 is bonded to the bump BP. The first pad PD1 and the bump BP, which move away from each other due to the stress, may be fixed by the protruded second portion SP1-2. Therefore, the bonding reliability may be enhanced, and the bonding resistance may be stable.

FIG. 14C is a plan view showing a structure in which a first insulating pattern SP1 faces a second insulating pattern SP2 and a hole SP-H of an insulating pattern is formed between the first insulating pattern SP1 and the second insulating pattern SP2.

FIG. 14D shows a structure in which a first insulating pattern SP1 faces a second insulating pattern SP2 and the first and second insulating patterns SP1 and SP2 are arranged in a diagonal direction with respect to the first direction DR1 and the second direction DR2. However, the direction in which the first insulating pattern and the second insulating pattern are arranged should not be limited to the diagonal direction with respect to the first direction DR1 and the second direction DR2 as long as the arranged direction is inclined.

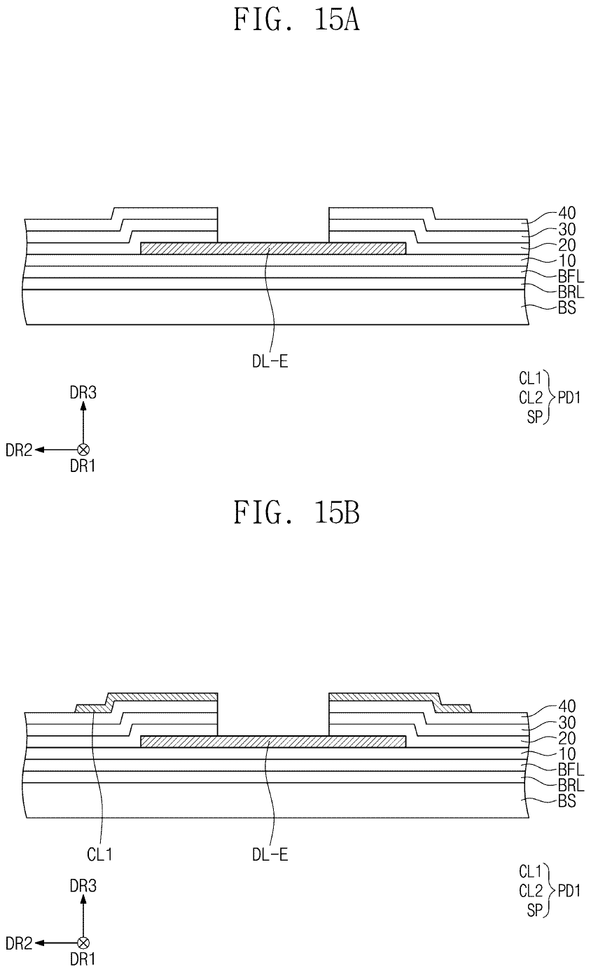

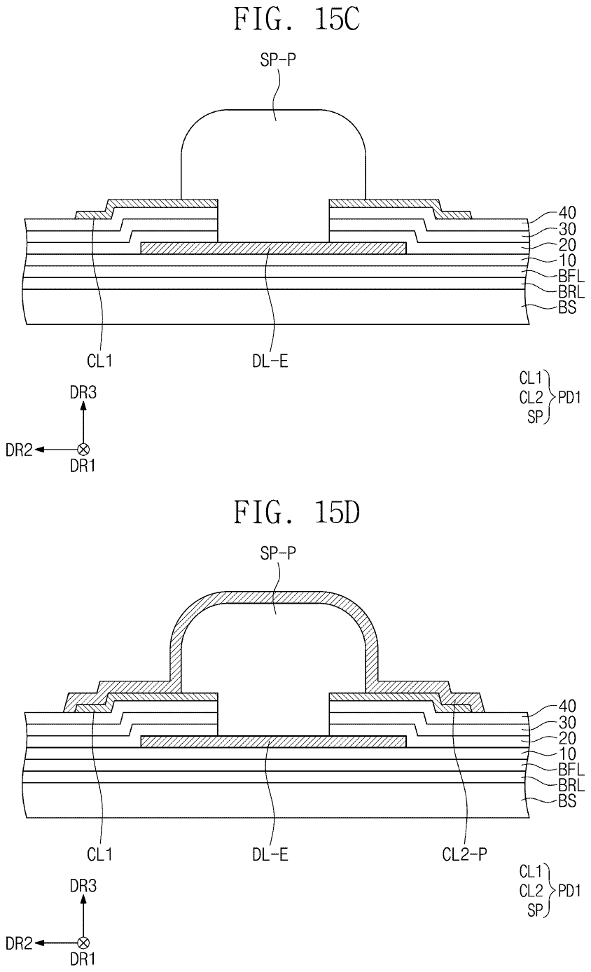

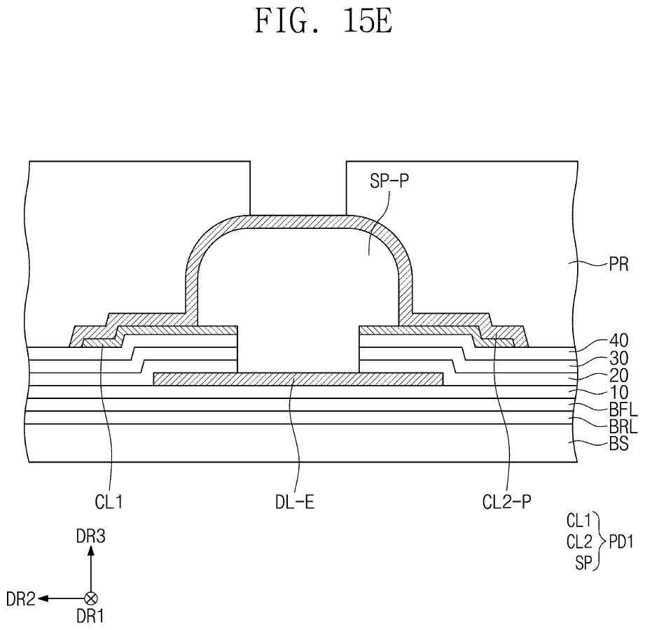

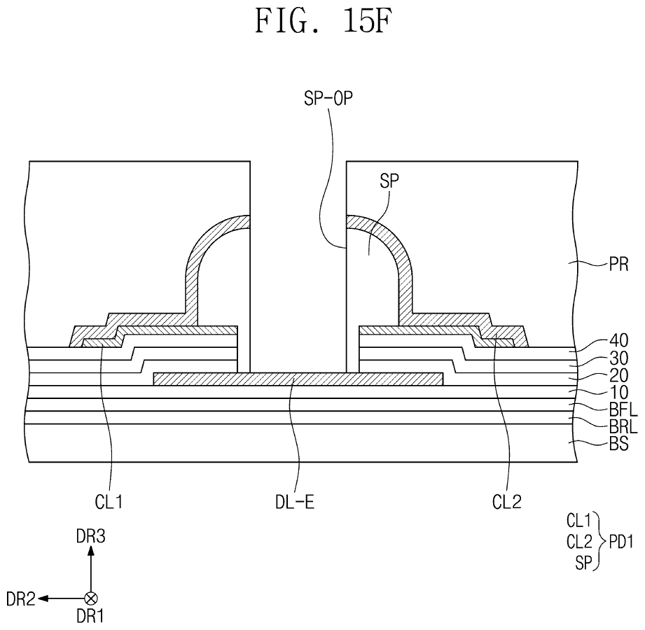

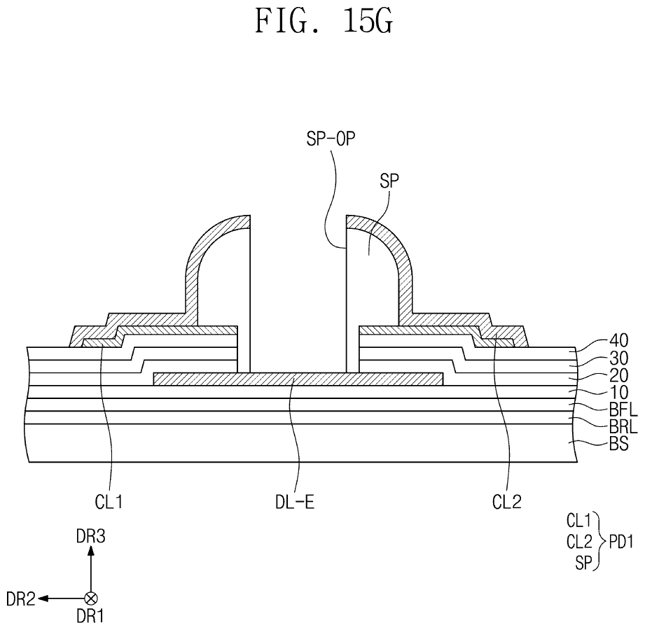

FIGS. 15A to 15G are cross-sectional views of an embodiment of a method of manufacturing an electronic device according to the disclosure. In FIGS. 15A to 15G, the same reference numerals denote the same elements in FIGS. 1 to 14C, and thus, detailed descriptions of the same elements will be omitted.

Referring to FIGS. 15A and 15B, the base layer BS, the barrier layer BRL, the buffer layer BFL, and the first insulating layer 10 are sequentially formed, and the end part DL-E of the signal line is formed on the first insulating layer 10. The second insulating layer 20, the third insulating layer 30, and the fourth insulating layer 40 may be sequentially formed on the first insulating layer 10 to expose the portion of the end part DL-E of the signal line. In addition, the first conductive pattern CL1 may be formed on the fourth insulating layer 40 to expose the portion of the end part DL-E of the signal line. The first conductive pattern CL1 may include the same material as that of the first connection electrode CNE1 of FIG. 5 and may be formed through the same process as the first connection electrode CNE1 of FIG. 5.

Referring to FIG. 15C, a preliminary insulating pattern SP-P may be formed on the end part DL-E of the signal line. The preliminary insulating pattern SP-P may be formed to contact the end part DL-E of the signal line and to cover a portion of the first conductive pattern CL1. The preliminary insulating pattern SP-P may have the dome shape protruded toward the third direction DR3.

Referring to FIG. 15D, a preliminary second conductive pattern CL2-P may be formed on the fourth insulating layer 40 to cover the preliminary insulating pattern SP-P. A portion of the preliminary second conductive pattern CL2-P may overlap the preliminary insulating pattern SP-P, and a portion of the preliminary second conductive pattern CL2-P, which does not overlap the preliminary insulating pattern SP-P, may contact the first conductive pattern CL1. The preliminary second conductive pattern CL2-P may include the same material as that of the second connection electrode CNE2 of FIG. 5 and may be formed through the same process.

Referring to FIG. 15E, a photoresist pattern PR through which a photo opening is defined may be formed on the fourth insulating layer 40 and the preliminary second conductive pattern CL2-P. The photoresist pattern PR may be formed by forming a photoresist layer including a photosensitive material and irradiating a light to a portion of the photoresist layer, which corresponds to the photo opening, or irradiating the light to portions except the photo opening. The photo opening may correspond to the opening SP-OP (refer to FIG. 15F) of the insulating pattern described later.

Referring to FIG. 15F, the preliminary second conductive pattern CL2-P and the preliminary insulating pattern SP-P may be etched to define the opening SP-OP through which the portion of the end part DL-E of the signal line is exposed. That is, the preliminary second conductive pattern CL2-P and the preliminary insulating pattern SP-P, which do not overlap the photoresist layer, may be etched. In this case, the preliminary second conductive pattern CL2-P and the preliminary insulating pattern SP-P may be dry-etched. Referring to FIG. 15G, the photoresist pattern PR (refer to FIG. 15F) may be removed.

Although the embodiments of the disclosure have been described, it is understood that the disclosure should not be limited to these embodiments but various changes and modifications may be made by one ordinary skilled in the art within the spirit and scope of the disclosure as hereinafter claimed. Therefore, the disclosed subject matter should not be limited to any single embodiment described herein, and the scope of the inventive concept shall be determined according to the attached claims.

What is claimed is:

1. An electronic device comprising:
an electronic component comprising a bump; and
a display panel electrically connected to the electronic component, the display panel comprising:
a display area;
a non-display area which is disposed next to the display area and in which the electronic component is disposed;
a base layer;
a pixel disposed on the base layer;
a signal line electrically connected to the pixel; and
a signal pad electrically connected to the signal line, the signal pad comprising:
a first conductive pattern connected to an end part of the signal line;
a second conductive pattern disposed on the first conductive pattern and connected to the first conductive pattern; and
an insulating pattern disposed between the end part of the signal line and the second conductive pattern,
wherein an opening is defined through the second conductive pattern and the insulating pattern and overlaps the end part of the signal line, and
the bump contacts the second conductive pattern.

2. The electronic device of claim 1, wherein a width of the opening measured at an upper surface of the insulating pattern is smaller than a width of the opening measured at a lower surface of the insulating pattern.

3. The electronic device of claim 1, wherein the opening comprises a first area and a second area under the first area, and a width of the first area is smaller than a width of the second area.

4. The electronic device of claim 1, wherein the opening has a bottle shape in a cross-section.

5. The electronic device of claim 1, wherein the insulating pattern comprises a material with a lower hardness than a hardness of the second conductive pattern.

6. The electronic device of claim 1, wherein a center of the opening of the insulating pattern corresponds to a center of the bump.

7. The electronic device of claim 1, wherein the insulating pattern comprises a first portion next to the bump and a second portion under the first portion, and the first portion protrudes toward a center of the bump further than the second portion.

8. The electronic device of claim 1, wherein the display panel further comprises an adhesive layer which contacts the signal pad and the bump.

9. The electronic device of claim 8, wherein the adhesive layer is filled into an inner side surface of the opening.

10. The electronic device of claim 1, wherein an opening is defined through the first conductive pattern and corresponds to the opening defined through the insulating pattern.

11. The electronic device of claim 1, wherein the display panel further comprises a plurality of insulating layers disposed on the base layer and covering the end part of the signal line, and an opening is defined through the plurality of insulating layers and corresponds to the opening defined through the insulating pattern.

12. The electronic device of claim 11, wherein a portion of the insulating pattern is disposed in the opening defined through the plurality of insulating layers, and the portion of the insulating pattern contacts an inner side surface of the plurality of insulating layers through which the opening is defined.

13. The electronic device of claim 1, wherein the signal pad further comprises a third conductive pattern comprising a first portion disposed on the second conductive pattern and a second portion disposed in the opening defined through the insulating pattern.

14. The electronic device of claim 1, wherein the end part of the signal line extends in a first direction in a plan view, and
the insulating pattern is provided in plural in a manner that insulating patterns are arranged in the first direction.

15. The electronic device of claim 14, wherein the display panel further comprises a plurality of insulating layers disposed on the end part of the signal line, and the end part of the signal line is connected to the first conductive pattern via a contact hole penetrating through the plurality of insulating layers.

16. An electronic device comprising:
an electronic component comprising a bump; and
a display panel electrically connected to the electronic component, the display panel comprising:
a display area;
a non-display area next to the display area;
a base layer;
a pixel disposed on the base layer;
a signal line electrically connected to the pixel; and
a signal pad electrically connected to the signal line, the signal pad comprising:
a first conductive pattern connected to an end part of the signal line;
a second conductive pattern disposed on the first conductive pattern and connected to the first conductive pattern; and
an insulating pattern disposed between the end part of the signal line and the second conductive pattern, the insulating pattern comprising:
a first portion; and
a second portion disposed on the first portion,
wherein the bump contacts the second conductive pattern, and
at least a portion of the second portion protrudes from the first portion toward a center of the bump.

17. The electronic device of claim 16, wherein the second portion has a width greater than a width of the first portion in a cross-section.

18. The electronic device of claim 16, wherein the first portion of the insulating pattern extends to contact one side surface of the first conductive pattern in a cross-section.

19. The electronic device of claim 16, wherein, in a plan view, the end part of the signal line extends in a first direction, the insulating pattern is provided in plural, the insulating patterns comprise first insulating patterns and second insulating patterns, which are arranged in a zigzag pattern in a second direction intersecting the first direction, and the insulating patterns are arranged in the first direction.

20. The electronic device of claim 16, wherein, in a plan view, the end part of the signal line extends in a first direction,
the insulating pattern comprises a first insulating pattern and a second insulating pattern facing the first insulating pattern in a second direction intersecting the first direction, and
the insulating pattern is provided in plural in a manner that insulating patterns are arranged in the first direction.
